(19) United States
(12) Patent Application Publication
(10) Pub. No.: US 2026/0122987 A1
(43) Pub. Date: Apr. 30, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Zhi-Chang LIN, Zhubei City (TW)

(21) Appl. No.: 18/926,692

(22) Filed: Oct. 25, 2024

(51) Int. Cl. H01L 29/06; H01L 29/417; H01L 29/423; H01L 29/66; H01L 29/775; H01L 29/786

(52) U.S. Cl. CPC H10D 62/121; H10D 30/014; H10D 30/43; H10D 30/6729; H10D 30/6735; H10D 30/6757; H10D 64/017; H10D 64/018

(57) ABSTRACT

A method of forming a semiconductor structure, including forming a fin structure over a substrate, forming a dummy gate structure over the fin structure, and etching the fin structure to form source/drain trenches on opposite sides of the dummy gate structure. The method further includes forming first source/drain features in the source/drain trenches, depositing bottom isolation layers on top surfaces of the first source/drain features, and forming second source/drain features over the bottom isolation layers. The second source/drain features are spaced apart from the bottom isolation layers. The method further includes depositing first contact etch stop layers (CESLs) in the source/drain trenches, and depositing an interlayer dielectric (ILD) layer on the first CESLs. The first CESLs cover top surfaces of the bottom isolation layers and surround the second source/drain features. The ILD layer fills spaces between the first source/drain features and the second source/drain features.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As IC technologies progress towards smaller technology nodes, the gate-all-around (GAA) devices have been introduced to improve gate control by increasing gate-channel coupling, reducing off-state current, and reducing short-channel effects (SCEs). As GAA devices continue to be developed, complementary metal-oxide-semiconductor field effect transistors (CMOSFET or CFET) has been provided due to their high noise immunity and low static power consumption. However, although existing technologies for fabricating CFETs have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an X-Z cross-sectional view of a semiconductor device, in accordance with some embodiments of the present disclosure.

FIG. 1B is a Y-Z cross-sectional view of the semiconductor device, in accordance with some embodiments of the present disclosure.

FIG. 1C is a Y-Z cross-sectional view of the semiconductor device, in accordance with some embodiments of the present disclosure.

FIG. 2A is an X-Z cross-sectional view of a semiconductor device, in accordance with some alternative embodiments of the present disclosure.

FIG. 2B is a Y-Z cross-sectional view of the semiconductor device, in accordance with some alternative embodiments of the present disclosure.

FIGS. 3-5 are perspective views of a workpiece at various fabrication stages, in accordance with some embodiments of the present disclosure.

FIGS. 6A, 7A, 8A, 9A, 10A, 11A, 12A, 13A, 14A, 15A, 16A, 17A, and 18A are X-Z cross-sectional views of the workpiece at various fabrication stages along line A-A′ of FIG. 5, in accordance with some embodiments of the present disclosure.

FIGS. 6B, 7B, 8B, 9B, 10A, 11A, 12B, 13B, 14B, 15B, 16B, 17B, and 18B are Y-Z cross-sectional views of the workpiece at various fabrication stages along line B-B′ of FIG. 5, in accordance with some embodiments of the present disclosure.

FIGS. 6C, 7C, 17C, and 18C are Y-Z cross-sectional views of the workpiece at various fabrication stages along line C-C′ of FIG. 5, in accordance with some embodiments of the present disclosure.

FIGS. 19A, and 20A are X-Z cross-sectional views of a workpiece at various fabrication stages along line A-A′ of FIG. 5, in accordance with some alternative embodiments of the present disclosure.

FIGS. 19B, and 20B are Y-Z cross-sectional views of the workpiece at various fabrication stages along line B-B′ of FIG. 5, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as three-dimensional complementary field effect transistors (CFETs) with gate-all-around (GAA) structures. Generally, a CFET may include an n-type FET (NFET) and a p-type FET (PFET) disposed vertically with a plurality of vertically stacked nanostructures (e.g., nanosheets, nanowires, or nanorods) in a channel region of the CFET, thereby allowing better gate control, lowered leakage current, and improved scaling capability for various IC applications.

The GAA structures may be patterned by any suitable method. For example, the GAA structures may be patterned using one or more photolithography processes, including double-patterning or multi-patterning processes. Generally speaking, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and is patterned using a photolithography process. Spacers are formed alongside the patterned sacrificial layer using a self-aligned process. The sacrificial layer is then removed, and the remaining spacers may then be used to pattern the GAA structure.

In the existing process for manufacturing CFET device, the lower source/drain (S/D) features of NFET or PFET and the upper S/D features of PFET or NFET are formed in source/drain trenches, and are vertically separated from each other by the separation structures. The formation of the separation structures includes depositing material layers and etching back the material layers in the S/D trenches. However, the aspect ratio of the S/D trenches is continuously increased since the dimensions of semiconductor device continue to scale down, and thus the difficulty in forming the separation structures in the S/D trenches is also increased. For example, the flatness and the process variation of the separation structures formed in the S/D trenches with high aspect ratio may be not good enough, and voids may occur between the separation structures and the upper S/D features.

Embodiments of the present disclosure offer advantages over the existing art, though it is understood that other embodiments may offer different advantages, not all advantages are necessarily discussed herein, and no particular advantage is required for all embodiments. For example, embodiments discussed herein include structures and methods that include forming bottom isolation layers on the lower S/D features, and forming upper S/D features that is spaced apart from the bottom isolation layers. Then, the separating structures are formed to fill the spaces between the bottom isolation layers and the upper S/D features (i.e., between the lower S/D features and the upper S/D features). In this way, the etching back process can be omitted, and thus the issues of flatness, process variation, and voids described above can be avoided and the cost can be reduced. Moreover, the embodiments discussed herein include structures and methods that include forming side spacers on opposite sides of the lower S/D features and that have top surfaces that are level with or higher than the top surfaces of the lower S/D features. The side spacers can facilitate the formation of bottom isolation layers, so as to increase the uniformity of the bottom isolation layers. As a result, the uniformity of the assembly of the bottom isolation layers and the separating structures may be improved.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise indicated.

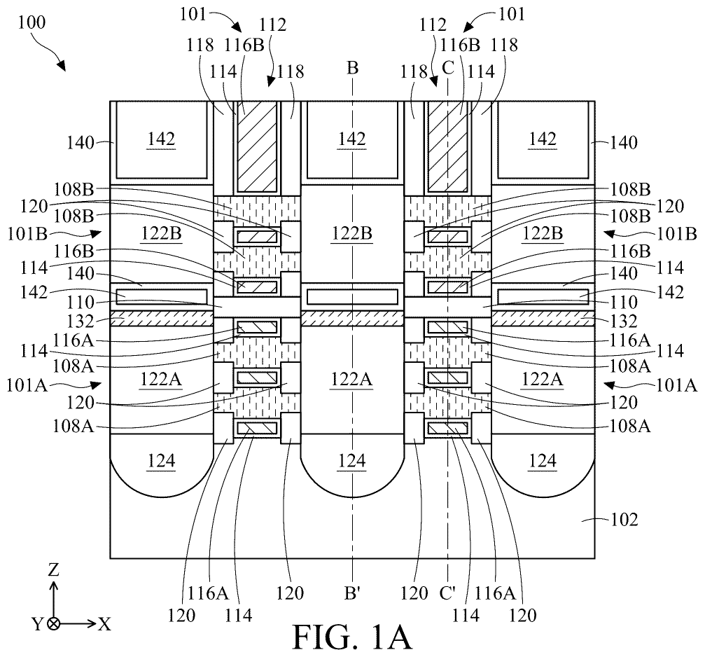

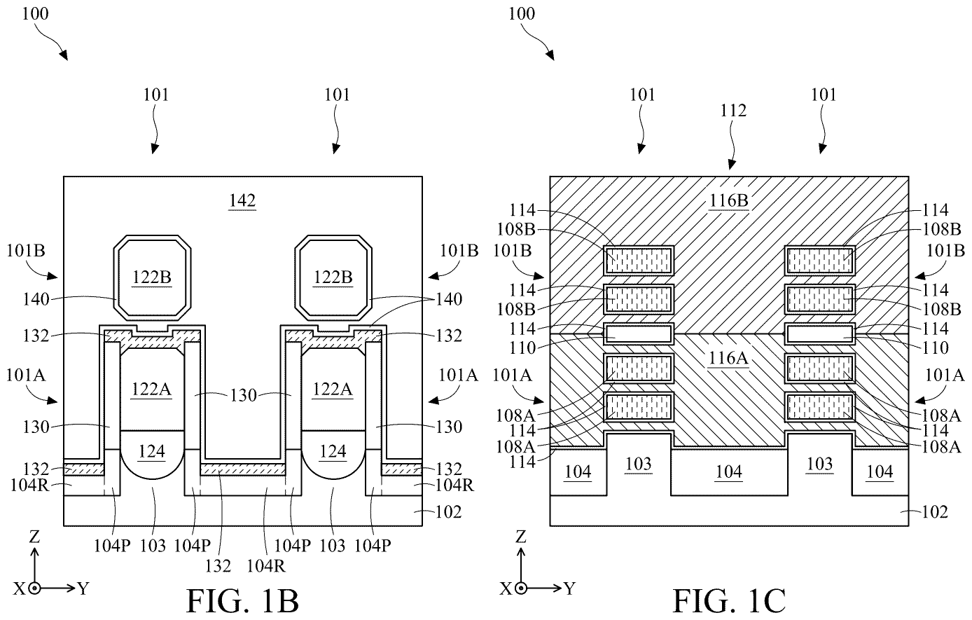

FIG. 1A is an X-Z cross-sectional view of a semiconductor device 100, in accordance with some embodiments of the present disclosure. FIG. 1B and FIG. 1C are Y-Z cross-sectional views of the semiconductor device 100 along line B-B′ and line C-C′ of FIG. 1A, respectively, in accordance with some embodiments of the present disclosure.

Referring to FIGS. 1A-1C, semiconductor device 100 includes complementary field effect transistors (CFETs) 101 that are arranged in the X-direction and the Y-direction, in accordance with some embodiments. Each of the CFETs 101 has a lower device 101A and an upper device 101B disposed over (or vertically overlaps) the lower device 101A in the Z-direction, as shown in FIGS. 1A-1C. In some embodiments, the lower device 101A may be a p-type field effect transistor (PFET) and the upper device 101B may be an n-type field effect transistor (NFET). In other embodiments, the lower device 101A may be an NFET and the upper device 101B may be a PFET.

The semiconductor device 100 further includes a substrate 102, as shown in FIGS. 1A-1C. The substrate 102 includes base portions 103 that are protruded from the substrate 102 under the nanostructures (e.g., nanostructures 108A and 108B described below). Subsequent features for the CFETs 101 are formed over the base portions 103 of the substrate 102, as described in further detail below. In some embodiments, after the resultant lower devices 101A and upper devices 101B of the CFETs 101 are formed, the substrate 102 may be thinned (or partially removed) by a suitable process (e.g., a chemical mechanical polishing (CMP) process) for forming backside interconnection.

In some embodiments, the semiconductor device 100 further includes isolation structures 104 in and/or over the substrate 102. The isolation structures 104 are formed between the base portions 103 of the substrate 102. In some embodiments, top surfaces of the isolation structures 104 are lower than top surfaces of the substrate 102 (more specifically, top surfaces of the base portions 103). In some embodiments, the isolation structures 104 include protruding portions 104P and recessed portions 104R. The top surfaces of the protruding portions 104P may be higher than the top surfaces of the recessed portions 104R. In some embodiments, the protruding portions 104P are formed on opposite sides of the base portions 103 in the Y-direction, and the recessed portions 104R are formed between the protruding portions 104P.

Still referring to FIGS. 1A-1C, the semiconductor device 100 further includes two groups of nanostructures, such as a group of nanostructures 108A and a group of nanostructures 108B (which may be collectively referred to as the nanostructures 108), in accordance with some embodiments. The nanostructures 108 may also be referred to as channels, channel layers, nanosheets, or nanowires. In some embodiments, the nanostructures 108B are disposed over (or vertically overlap) the nanostructures 108A in the Z-direction. The nanostructures 108A are used for the lower devices 101A in the CFETs 101 and the nanostructures 108B are used for the upper devices 101B in the CFETs 101. Furthermore, the nanostructures 108 are suspended over the base portions 103 of the substrate 102.

In some embodiments, the semiconductor device 100 further includes middle insulators 110 that are disposed between the topmost nanostructures 108A and the bottommost nanostructures 108B, such that the group of nanostructures 108A and the group of nanostructures 108B are separated from each other by the middle insulators 110. In some embodiments, the nanostructures 108 and the middle insulators 110 are extended in the X-direction and vertically stacked (or arranged) in the Z-direction. In the Z-direction, the nanostructures 108 may be spaced apart from each other, and the topmost nanostructures 108A and the bottommost nanostructures 108B may be spaced apart from the middle insulators 110.

In some embodiments, two nanostructures 108 are vertically stacked (or arranged) from each other in the Z-direction for one transistor. For example, in CFET 101, the lower device 101A has two nanostructures 108A vertically stacked from each other in the Z-direction, and the upper device 101B has two nanostructures 108B vertically stacked from each other in the Z-direction, as shown in FIGS. 1A and 1C. However, there may be another appropriate number of nanostructures in one transistor. For example, there may be 1, 3, 4, or more than 4 nanostructures 108 in one transistor.

Still referring to FIGS. 1A-1C, the semiconductor device 100 further includes gate structures 112 wrapped around the nanostructures 108, in accordance with some embodiments. The gate structure 112 may be wrapped around the nanostructures 108A in the lower device 101A and the nanostructures 108B in the upper device 101B. The CFETs 101 disposed along the Y-direction may share the same gate structure 112 that extends in the Y-direction.

The gate structure 112 includes a gate dielectric layer 114, a gate electrode layer 116A, and a gate electrode layer 116B (the gate electrode layers 116A and 116B may be collectively referred to as the gate electrode layers 116). In some embodiments, the gate dielectric layer 114 wraps around each of the nanostructures 108 and the middle insulators 110, as shown in FIGS. 1A and 1C. The gate electrode layer 116A may be wrapped around the portions of the gate dielectric layer 114 that are wrapped around the nanostructures 108A, so as to form a first gate structure used for the lower device 101A of the CFET 101. The gate electrode layer 116B may be wrapped around the portions of the gate dielectric layer 114 that are wrapped around the nanostructures 108B, so as to form a second gate structure used for the upper device 101B of the CFET 101. The gate structure 112 may be constituted by the first gate structure and the second gate structure.

In some embodiments, the gate dielectric layer 114 is also formed on the top surfaces of the isolation structures 104 and on the top surfaces and sidewalls of the substrate 102 (e.g., the top surfaces and sidewalls of the base portions 103). In some embodiments, the gate dielectric layer 114 is further be formed on the sidewalls of gate spacers 118 and inner spacers 120 (discussed below), as shown in FIG. 1A. In some embodiments, the top surface of the gate electrode layer 116A is lower than the top surface of the middle insulator 110, and the bottom surface of the gate electrode layer 116B is higher than the bottom surface of the middle insulator 110, as shown in FIG. 1C. In some embodiments, the gate structure 112 further includes an interfacial layer (not shown) formed between the gate dielectric layer 114 and the nanostructures 108.

Still referring to FIGS. 1A-1C, the semiconductor device 100 further includes gate spacers 118 formed on opposite sides of the gate structures 112, in accordance with some embodiments. More specifically, the gate spacers 118 are formed on the sidewalls of the gate structures 112 and over the nanostructures 108, as shown in FIG. 1A. Furthermore, the gate spacers 118 may extend lengthwise in the Y-direction (e.g., parallel to the gate structures 112), and are on opposite sides (or on opposite sidewalls) of the gate structures 112 in the X-direction. The gate spacers 118 are located over the topmost nanostructures 108B and on the top sidewalls of the gate structures 112, and thus are also referred to as gate top spacers or top spacers.

In some embodiments, the semiconductor device 100 further includes inner spacers 120 formed on opposite sides of the gate structures 112. More specifically, the inner spacers 120 are formed on the sidewalls of the gate structure 112, and below the gate spacers 118 and the topmost nanostructures 108B. In some embodiments, the inner spacers 120 are also formed vertically between the adjacent nanostructures 108A, between the adjacent nanostructures 108B, between the topmost nanostructures 108A and the middle insulators 110, between the bottommost nanostructures 108B and the middle insulators 110, and between the bottommost nanostructures 108A and the substrate 102, as shown in FIG. 1A. In some embodiments, the inner spacers 120 are laterally between the source/drain features 122A/122B (described below) and the gate structures 112 in the X-direction.

Still referring to FIGS. 1A-1C, each of the CFETs 101 includes source/drain features 122A and 122B (may be collectively referred to as the source/drain features 122) over the substrate 102, in accordance with some embodiments. More specifically, the source/drain features 122A are disposed over the substrate 102, and the source/drain features 122B are disposed over (or vertically overlap) the source/drain features 122A. In some embodiments, the source/drain features 122B are vertically separated from the source/drain features 122A in the Z-direction, as shown in FIGS. 1A and 1B. In some embodiments, the source/drain features 122A are disposed on the opposite sides of the gate structures 112 (e.g., the gate electrode layers 116A) in the X-direction to form lower devices 101A, as shown in FIG. 1A. Similarly, the source/drain features 122B are disposed on the opposite sides of the gate structure 112 (e.g., the gate electrode layers 116B) in the X-direction to form the upper devices 101B, as shown in FIG. 1A.

The nanostructures 108A extend in the X-direction to connect one source/drain feature 122A to another source/drain feature 122A, and the nanostructures 108B extend in the X-direction to connect one source/drain feature 122B to another source/drain feature 122B, in accordance with some embodiments. Specifically, the source/drain features 122A are disposed on opposite sides of the nanostructures 108A in the X-direction, and the source/drain features 122B are disposed on opposite sides of the nanostructures 108B in the X-direction. Therefore, the source/drain features 122A are attached and electrically connected to the nanostructures 108A in the X-direction, and the source/drain features 122B are attached and electrically connected to the nanostructures 108B in the X-direction. The source/drain features 122A and 122B may also be referred to as source/drain, or source/drain regions. In some embodiments, source/drain feature(s) may refer to a source or a drain, individually or collectively dependent upon the context.

Still referring to FIGS. 1A-1C, the semiconductor device 100 further includes undoped epitaxial layers 124 formed under the source/drain features 122A and over the substrate 102 in the Z-direction, in accordance with some embodiments. In some embodiments, the undoped epitaxial layers 124 are vertically between and in direct contact with the source/drain features 122A and the substrate 102 in the Z-direction. In some embodiments, the top surfaces of the undoped epitaxial layers 124 are higher than the bottommost surfaces of the gate structures 112, as shown in FIG. 1A. In other embodiments, the undoped epitaxial layers 124 are omitted from the semiconductor device 100.

In some embodiments, the semiconductor device 100 further includes isolation layers (not shown) under the source/drain features 122A and over the undoped epitaxial layers 124 in the Z-direction. In some embodiments, the isolation layers are vertically between and in contact with the source/drain features 122A and the undoped epitaxial layers 124. In some embodiments, the top surfaces of the isolation layers are higher than the topmost surfaces of the substrate 102, so as to ensure that the isolation layers separate the source/drain features 122A from the substrate 102. In other embodiments, the undoped epitaxial layers 124 are omitted, so that the isolation layers are vertically between and in direct contact with the source/drain features 122A and the substrate 102.

Still referring to FIGS. 1A-1C, the semiconductor device 100 further includes side spacers 130 formed on opposite sides of the source/drain features 122A in the Y-direction, in accordance with some embodiments. More specifically, the source/drain features 122A are formed between the side spacers 130. In some embodiments, the top surfaces of the side spacers 130 are higher than the top surfaces of the source/drain features 122A, as shown in FIG. 1B. In other embodiments, the top surfaces of the side spacers 130 are level with the top surfaces of the source/drain features 122A. In some embodiments, the top surfaces of the side spacers 130 are higher than the top surfaces of the topmost nanostructures 108A. In some embodiments, the undoped epitaxial layers 124 are also formed between the side spacers 130, so that the side spacers 130 are in contact with both of the source/drain features 122A and the undoped epitaxial layers 124. In some embodiments, the side spacers 130 are directly on the respective protruding portions 104P of the isolation structures 104, as shown in FIG. 1B. Therefore, the recessed portions 104R are also between the side spacers 130.

Still referring to FIGS. 1A-1C, the semiconductor device 100 further includes bottom isolation layers 132 formed on the source/drain features 122A, in accordance with some embodiments. More specifically, the bottom isolation layers 132 are formed on the top surfaces of the source/drain features 122A and the top surfaces of the side spacers 130, as shown in FIGS. 1A and 1B. In some embodiments, since the top surfaces of the source/drain features 122A are lower than that of the side spacers 130, the bottom isolation layers 132 may have recessed portions that are directly over the source/drain features 122A. In some embodiments, the bottom isolation layers 132 are spaced apart from the source/drain features 122B in the Z-direction.

In some embodiments, the bottom isolation layers 132 are also formed on the top surfaces of the recessed portions 104R of the isolation structures 104 and between the protruding portions 104P, as shown in FIG. 1B. In some embodiments, the bottom isolation layers 132 are in partial contact with the middle insulators 110 and the inner spacers 120 that are below and in direct contact with the middle insulators 110. In other embodiments, the bottom isolation layers 132 are in partial contact with the middle insulators 110 and the inner spacers 120 that are above and in direct contact with the middle insulators 110. In certain embodiments, the bottom isolation layers 132 are in contact with the inner spacers 120 that are in direct contact with and below or above the middle insulators 110, without contacting middle insulators 110. In yet some embodiments, the bottom isolation layers 132 are in contact with the middle insulators 110, without contacting the inner spacers 120.

Still referring to FIGS. 1A-1C, the semiconductor device 100 further includes contact etch stop layers (CESLs) 140 formed over the source/drain features 122A and 122B, in accordance with some embodiments. More specifically, the CESLs 140 surround the source/drain features 122B, and are formed on and cover the bottom isolation layers 132 that are on the source/drain features 122A. The CESLs 140 may further be formed on the sidewalls of the gate spacers 118, the middle insulators 110, and some of the inner spacers 120, as shown in FIG. 1A. The CESLs 140 may further be formed on the sidewalls of the side spacers 130, on the top surfaces of the bottom isolation layers 132 formed on the recessed portions 104R, and/or on the sidewalls of the protruding portions 104P, as shown in FIG. 1B.

Still referring to FIGS. 1A-1C, the semiconductor device 100 further includes an interlayer dielectric (ILD) layer 142 formed over the CESLs 140, in accordance with some embodiments. The ILD layer 142 may fill the space between the CESLs 140. For example, the ILD layer 142 fills the space between the source/drain features 122A (or bottom isolation layers 132) and the source/drain features 122B. More specifically, the ILD layer 142 fills the spaces between the CESLs 140 formed on the bottom isolation layers 132 and the CESLs 140 surrounding the source/drain features 122B. In some embodiments, the source/drain features 122A and the source/drain features 122B are spaced apart from each other by the bottom isolation layers 132, the CESLs 140, and the ILD layer 142, as shown in FIGS. 1A and 1B.

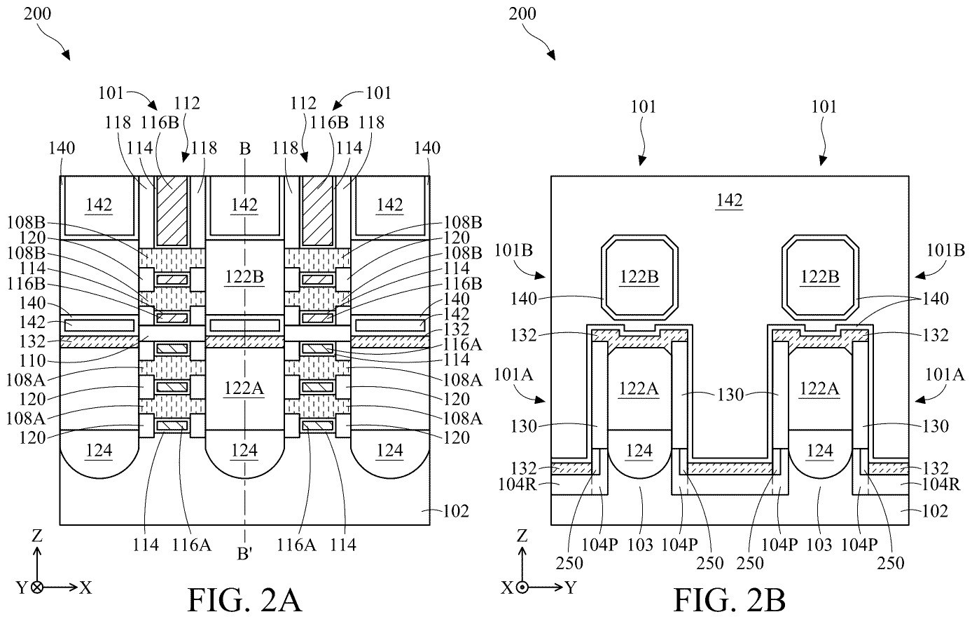

FIG. 2A is an X-Z cross-sectional view of a semiconductor device 200, in accordance with alternative embodiments of the present disclosure. FIG. 2B is a Y-Z cross-sectional view of the semiconductor device 200 along line B-B′ of FIG. 2A, in accordance with alternative embodiments of the present disclosure. The semiconductor device 200 shown in FIGS. 2A and 2B may be similar to the semiconductor device 100 shown in FIGS. 1A-1C, except the semiconductor device 200 further includes side dielectric layers 250 embedded in the isolation structures 104.

Referring to FIGS. 2A and 2B, the semiconductor device 200 further includes the side dielectric layers 250 that are embedded into the protruding portions 104P of the isolation structures 104, in accordance with some embodiments. More specifically, the side dielectric layers 250 are formed on opposite sides of the base portions 103 and are spaced apart from the base portions 103 by the remaining portions of the protruding portions 104P. In some embodiments, the side dielectric layers 250 are under and in contact with the side spacers 130, so that the side spacers 130 are over and in contact with both the side dielectric layers 250 and the protruding portions 104P, as shown in FIG. 2B. In some embodiments, the portions of the bottom isolation layers 132 formed on the recessed portions 104R are also between and in contact with the side dielectric layers 250. In some embodiments, the CESLs 140 are also formed on the sidewalls of the side dielectric layers 250.

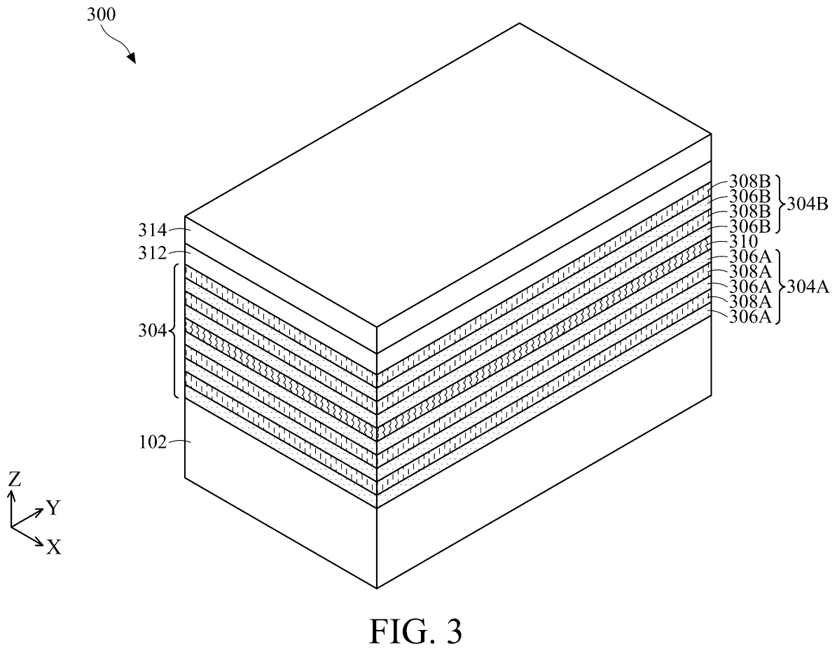

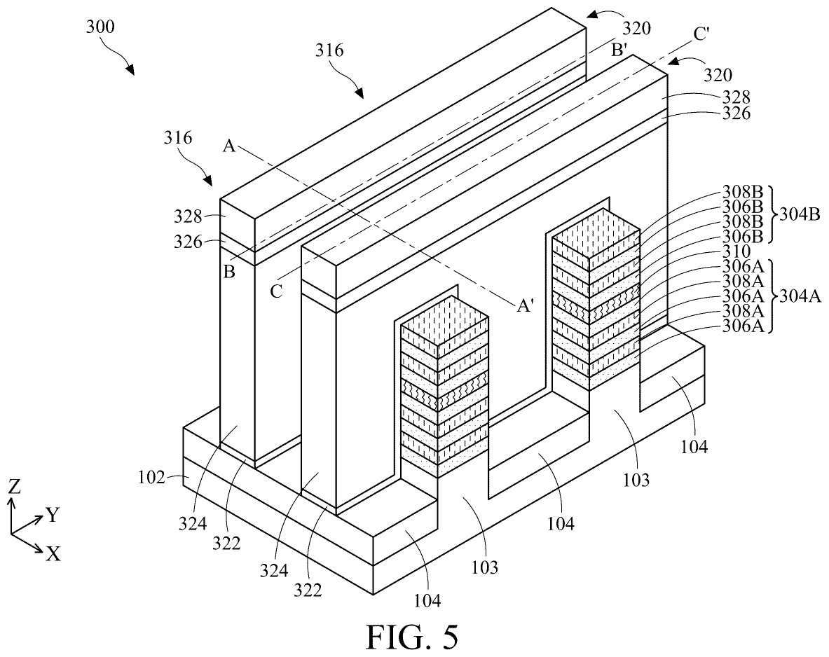

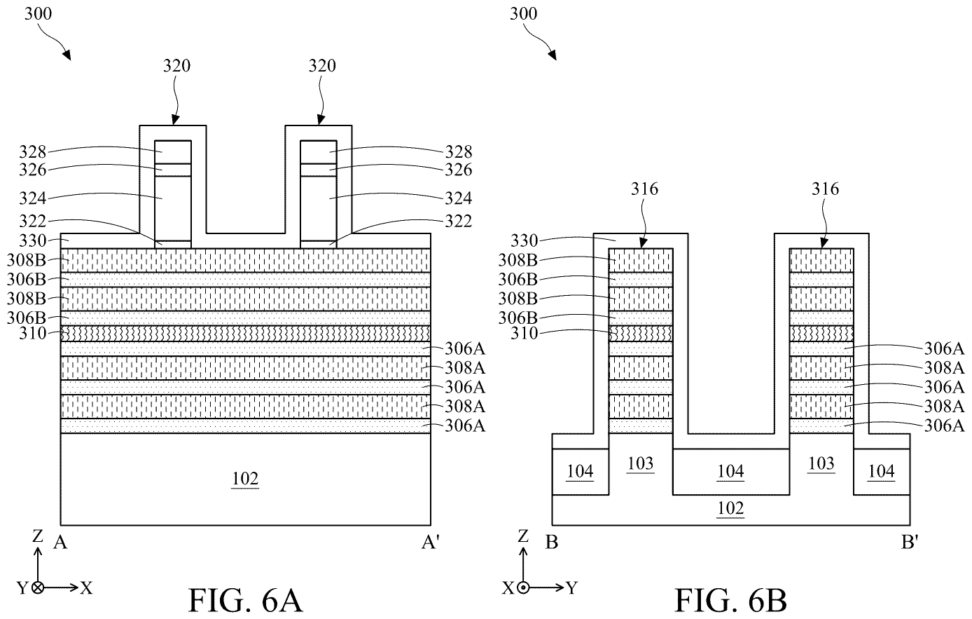

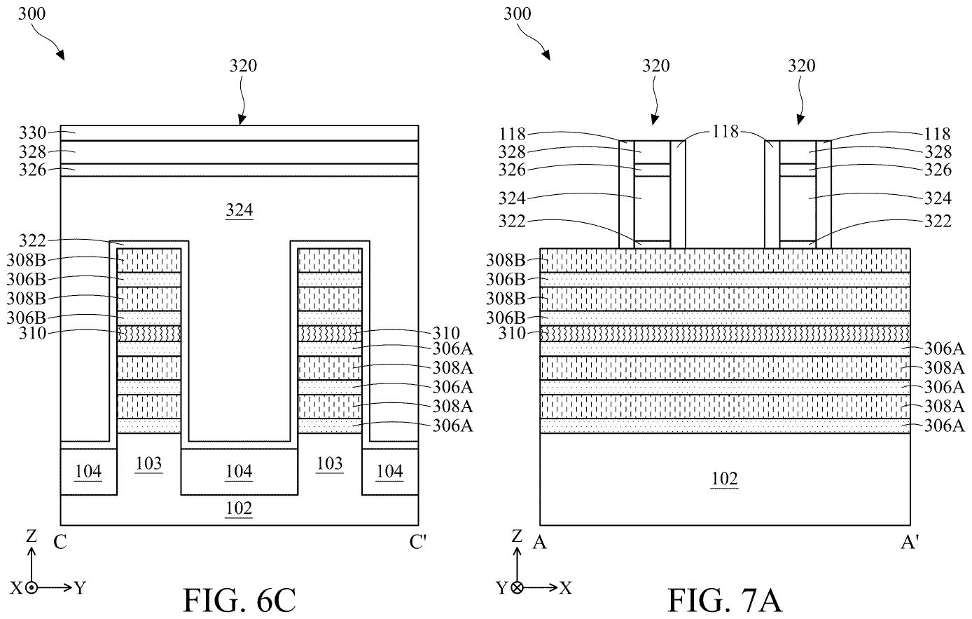

The formation of the semiconductor device (e.g., the semiconductor devices 100-200) are described in detail in below. The formation of the semiconductor device starts from a workpiece 300. FIGS. 3-5 are perspective views of the workpiece 300 at various fabrication stages, in accordance with some embodiments of the present disclosure. FIGS. 6A, 7A, 8A, 9A, 10A, 11A, 12A, 13A, 14A, 15A, 16A, 17A, and 18A are X-Z cross-sectional views of the workpiece 300 at various fabrication stages along line A-A′ of FIG. 5, in accordance with some embodiments of the present disclosure. FIGS. 6B, 7B, 8B, 9B, 10A, 11A, 12B, 13B, 14B, 15B, 16B, 17B, and 18B are Y-Z cross-sectional views of the workpiece 300 at various fabrication stages along line B-B′ of FIG. 5, in accordance with some embodiments of the present disclosure. FIGS. 6C, 7C, 17C, and 18C are Y-Z cross-sectional views of the workpiece 300 at various fabrication stages along line C-C′ of FIG. 5, in accordance with some embodiments of the present disclosure.

Referring to FIG. 3, the workpiece 300 is provided. The workpiece 300 includes a substrate 102 and a stack 304 over the substrate 102. In some embodiments, the substrate 102 contains a semiconductor material, such as bulk silicon (Si). In some embodiments, the substrate 102 may include other semiconductors such as germanium (Ge), silicon germanium (SiGe), or a III-V semiconductor material. Example III-V semiconductor materials may include GaAs, InP, GaP, GaN, GaAsP, AlInAs, AlGaAs, GaInP, and InGaAs. The substrate 102 may also include an insulating layer, such as a silicon oxide layer, to have a silicon-on-insulator (SOI) structure or a germanium-on-insulator (GOI) structure.

In some embodiments, the substrate 102 may include one or more well regions for forming different types of devices. For example, the well regions may be n-type well regions doped with an n-type dopant (e.g., phosphorus (P) or arsenic (As)) or p-type well regions doped with a p-type dopant (e.g., boron (B) or indium (In)). The n-type and p-type well regions may be formed by using ion implantation or thermal diffusion.

In some embodiments, the stack 304 includes a first stack 304A (including semiconductor layers 306A and semiconductor layers 308A), a semiconductor layer 310 over the first stack 304A, and a second stack 304B (including semiconductor layers 306B and semiconductor layers 308B) over the semiconductor layer 310. In some embodiments, the first stack 304A, the semiconductor layer 310, and the second stack 304B are stacked in the Z-direction. In some embodiments, the semiconductor layers 306A and the semiconductor layers 308A are stacked in an alternating manner in the Z-direction, and the semiconductor layers 306B and the semiconductor layers 308B are stacked in an alternating manner in the Z-direction, as shown in FIG. 3. In some embodiments, the semiconductor layer 310 is vertically between the first stack 304A and the second stack 304B. In further embodiments, the semiconductor layer 310 is in direct contact with the topmost semiconductor layer 306A of the first stack 304A and the bottommost semiconductor layer 306B of the second stack 304B.

In some embodiments, the semiconductor layers 306 (including semiconductor layers 306A and 306B), the semiconductor layers 308 (including semiconductor layers 308A and 308B), and the semiconductor layer 310 may have different semiconductor compositions. In some embodiments, the semiconductor layers 306 and 310 are formed of SiGe, and the semiconductor layers 308 are formed of Si. In these embodiments, the additional germanium content in the semiconductor layers 306 and 310 allows selective removal or recess of the semiconductor layers 306 and 310 without substantial damages to the semiconductor layers 308. In some embodiments, the semiconductor layer 310 functions as a placeholder for the middle insulators 110 that will be subsequently formed, and the semiconductor layers 306 are also referred to as sacrificial layers.

In some embodiments, the semiconductor layers 306 and 310 are formed of SiGe, and the Ge concentration of the semiconductor layer 310 is higher than the Ge concentration of the semiconductor layers 306. In these embodiments, the different germanium contents in the semiconductor layers 306 and the semiconductor layer 310 provide etching selectivity between the semiconductor layers 306 and semiconductor layer 310. For example, the semiconductor layer 310 may be substantially completely removed while the semiconductor layers 306 are partially removed, alternatively, the semiconductor layer 310 may be removed while the semiconductor layers 306 are substantially not etched.

In some embodiments, the semiconductor layers 306, 308, and 310 are epitaxially grown over or on the substrate 102 using an epitaxial growth such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized. The semiconductor layers 306A and 308A are deposited alternately, one-after-another, to form the first stack 304A. The semiconductor layer 310 is deposited over the first stack 304A. The semiconductor layers 306B and 308B are deposited alternately, one-after-another, over the semiconductor layer 310 to form the second stack 304B.

The two semiconductor layers 308A are used for the nanostructures 108A of the lower devices 101A, and the two semiconductor layers 308B are used for the nanostructures 108B of the upper devices 101B. It should be noted that, five layers of the semiconductor layers 306 and four layers of the semiconductor layers 308 are shown in FIG. 3, which are for illustrative purposes only and not intended to be limiting beyond what is specifically recited in the claims. The number of the semiconductor layers depends on the desired number of channel members for the semiconductor device.

For patterning purposes, the workpiece 300 may also include a hard mask layer structure over the stack 304. In some embodiments, the hard mask structure may be a multi-layer structure and includes, for example, a hard mask 312 and a hard mask 314 over the hard mask 312. In other embodiments, the hard mask structure may be a single layer structure.

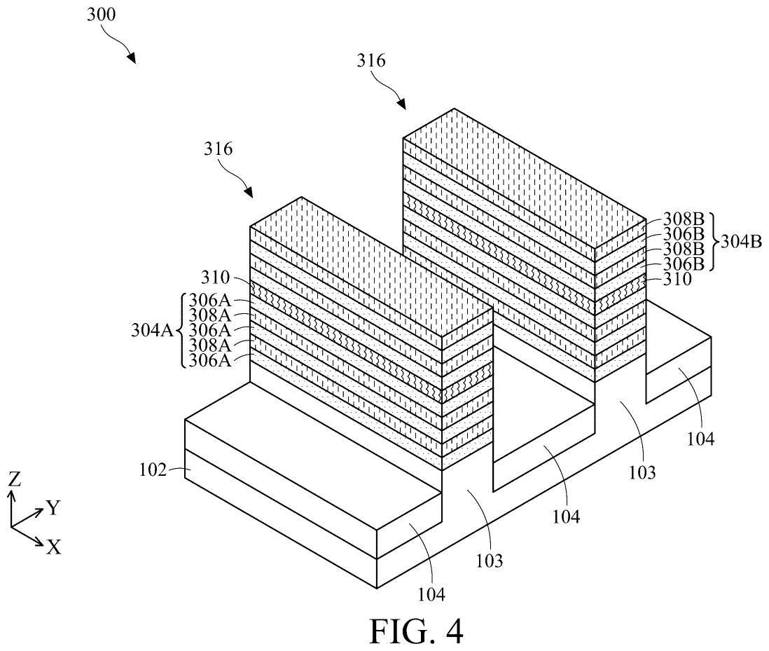

Referring to FIG. 4, the substrate 102 and the stack 304 are then patterned to form fin structures 316 over the substrate 102, in accordance with some embodiments. In some embodiments, each of the fin structures 316 includes a base portion (e.g., the base portions 103) formed from the substrate 102 and a stack portion formed from the stack 304 over the base portion, as shown in FIG. 4. The stack portion of each of the fin structures 316 includes the first stack 304A, the semiconductor layer 310 over the first stack 304A, and the second stack 304B over the semiconductor layer 310. The first stack 304A may include semiconductor layers 306A and 308A that are alternately stacked in the Z-direction, and the second stack 304B may include semiconductor layers 306B and 308B that are alternately stacked in the Z-direction. In some embodiments, the fin structures 316 extend in the X-direction, and are arranged in the Y-direction. Although the two fin structures 316 are formed and shown herein, more fin structures may be formed, such as three or more fin structures.

The fin structures 316 may be patterned using suitable processes including double-patterning or multi-patterning processes. For example, in some embodiments, a material layer is formed over the stack 304 and patterned using a photolithography process. Spacers are formed alongside the patterned material layer using a self-aligned process. The material layer is then removed, and the remaining spacers, or mandrels, may then be used to pattern the fin structures 316 by etching the stack 304 and the substrate 102. The etching process may include dry etching, wet etching, reactive ion etching (RIE), and/or other suitable processes.

Still referring to FIG. 4, the isolation structures 104 are formed, in accordance with some embodiments. After forming the fin structures 316, the hard masks 312 and 314 over the fin structures 316 are removed, and the isolation structures 104 are formed over the substrate 102. In some embodiments, the isolation structures 104 extend in the X-direction and are arranged with the fin structures 316 in the Y-direction. In other words, the isolation structures 104 are formed on opposite sides of the fin structures 316 in the Y-direction. In some aspects, the isolation structures 104 are formed around the fin structures 316.

The isolation structures 104 may include different structures, such as shallow trench isolation (STI) structures, deep trench isolation (DTI) structures, and/or local oxidation of silicon (LOCOS) structures. In some embodiments, the STI structures include a single layer structure. In other embodiments, the STI structures include a multi-layer structure that has a bulk dielectric layer disposed over a liner dielectric layer.

In some embodiments, the dielectric material for the isolation structures 104 is first deposited over the workpiece 300. Specifically, the dielectric material is deposited and formed over the fin structures 316 and the substrate 102 to cover the fin structures 316 and the substrate 102. In some embodiments, the dielectric material is formed to wrap around the fin structures 316. In some embodiments, the dielectric material may include silicon oxide (SiO₂), silicon nitride (Si₃N₄), silicon oxynitride (SiON), fluorine-doped silicate glass (FSG), a low-k dielectric material, other suitable materials, or combinations thereof. Exemplary low-k dielectric materials include carbon doped silicon oxide, xerogel, aerogel, amorphous fluorinated carbon, parylene, BCB-based dielectric material, polyimide, other low-k dielectric materials, or combinations thereof.

In some embodiments, the dielectric material is deposited using a deposition process, such as CVD, ALD, high-density plasma CVD (HDPCVD), MOCVD, RPCVD, PECVD, LPCVD, atomic layer CVD (ALCVD), atmospheric pressure CVD (APCVD), subatmospheric CVD (SACVD), flowable CVD (FCVD), spin-on coating, and/or other suitable process. The deposited dielectric material is then thinned and planarized, for example by a chemical mechanical polishing (CMP) process, until the hard masks 312 and 314 are removed. The planarized dielectric material is further recessed by a dry etching process, a wet etching process, or a combination thereof to form the isolation structures 104. In some embodiments, before forming the isolation structures 104, a liner layer may be conformally deposited over the substrate 102 using a deposition process, such as CVD, ALD, HDPCVD, MOCVD, RPCVD, PECVD, LPCVD, ALCVD, APCVD, FCVD, or combinations thereof. In some embodiments, the stack portions of the fin structures 316 rise above the isolation structures 104 while the base portions 103 are surrounded by the isolation structures 104, as shown in FIG. 4. In other words, the top surface of the substrate 102 is higher than the top surfaces of the isolation structures 104.

Referring to FIG. 5, dummy gate structures 320 are formed over the fin structures 316 and the isolation structures 104, in accordance with some embodiments. The dummy gate structures 320 are configured to extend lengthwise in the Y-direction and to wrap around the top surfaces and the side surfaces of the fin structures 316. In some embodiments, to form the dummy gate structure 320, a dummy gate dielectric material for dummy gate dielectric layers 322 is first formed over fin structures 316 and the isolation structures 104. In some embodiments, the dummy gate dielectric material may include, for example, a dielectric material such as a nitride (e.g., SiN, SiON), a carbide (e.g., silicon carbide (SiC)), an oxide (e.g., SiO₂), or other suitable material.

Then, in some embodiments, a dummy gate electrode material for dummy gate electrode layers 324 is formed on the dummy gate dielectric material. The dummy gate electrode material may include a conductive material selected from a group composed of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by way of a thermal oxidation process and/or a deposition process (e.g., physical vapor deposition (PVD), CVD, PECVD, and ALD).

Afterward, hard masks 326 and 328 are formed over the dummy gate electrode material. In some embodiments, the hard masks 326 and 328 may be formed using photolithography and etching processes. In some embodiments, the hard masks 326 and 328 may include photoresist materials or hard mask materials. In some embodiments, the hard mask 326 may be a silicon nitride layer and the hard mask 328 may be a silicon oxide layer.

After the formation of the hard masks 326 and 328, a removal process (e.g., etching) may be performed to remove portions of the dummy gate electrode material for the dummy gate electrode layers 324 and the dummy gate dielectric material for the dummy gate dielectric layers 322 that are not directly underlie the hard masks 326 and 328, thereby forming the dummy gate structures 320. Each of the dummy gate structures 320 has the dummy gate dielectric layer 322, the dummy gate electrode layer 324, and the hard masks 326 and 328. The dummy gate dielectric layers 322 may also be referred to as dummy interfacial layers.

The dummy gate structures 320 may undergo a gate replacement process through subsequent processing to form metal gates, such as a high-k metal gate, as discussed in greater detail below. FIG. 5 shows that the workpiece 300 has two dummy gate structures 320. In some embodiments, in the workpiece 300, less or more dummy gate structures may be formed for one or more transistors sharing source/drain regions.

Referring to FIGS. 6A-6C, after the formation of the dummy gate structures 320, a spacer layer 330 for the gate spacers 118 and the side spacers 130 is formed on the workpiece 300, in accordance with some embodiments. More specifically, the spacer layer 330 is conformally deposited over the fin structures 316, the dummy gate structures 320, and the isolation structures 104. The spacer layers 330 may be formed by CVD, PVD, ALD, HDPCVD, MOCVD, RPCVD, PECVD, LPCVD, ALCVD, APCVD, FCVD, or other suitable methods. The spacer layers 330 may include Si₃N₄, SiO₂, SiC, silicon oxycarbide (SiOC), SiON, silicon carbon nitride (SiCN), silicon oxycarbon nitride (SiOCN), carbon doped oxide, nitrogen doped oxide, porous oxide, or combinations thereof. In some embodiments, the spacer layers 330 include a low-k dielectric material, such as those described herein. The spacer layers 330 may include a single layer or a multi-layer structure.

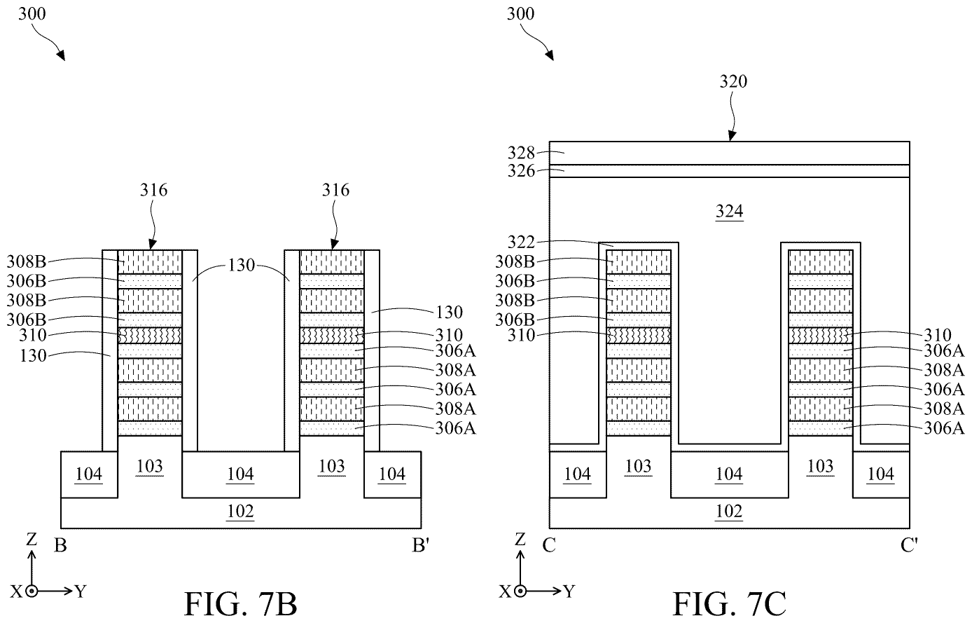

Referring to FIGS. 7A-7C, the gate spacers 118 are formed on opposite sides of the dummy gate structures 320 in the X-direction, and the side spacers 130 are formed on opposite sides of the fin structures 316 in the Y-direction, in accordance with some embodiments. In some embodiments, an anisotropic etching process is performed to remove horizontal portions of the spacer layer 330 from the top surfaces of the fin structures 316, the dummy gate structures 320, and the isolation structures 104. In some embodiments, the anisotropic etching process is a dry (e.g., plasma) etching process

After the anisotropic etching process, the portions of the spacer layer 330 on the sidewall surfaces of the dummy gate structures 320 substantially remain and become the gate spacers 118. That is, the gate spacers 118 are formed on opposite sides of the dummy gate structures 320 in the X-direction, and formed on the sidewall surfaces of the dummy gate structures 320. After the anisotropic etching process, the portions of the spacer layer 330 on the sidewall surfaces of the fin structures 316 substantially remain and become the side spacers 130. That is, the side spacers 130 are formed on opposite sides of the fin structures 316 in the Y-direction, and formed on the sidewall surfaces of the fin structures 316. In some embodiments, the gate spacers 118 are also in partial contact with the fin structures 316 and the isolation structures 104, and the side spacers 130 are also in partial contact with the isolation structures 104.

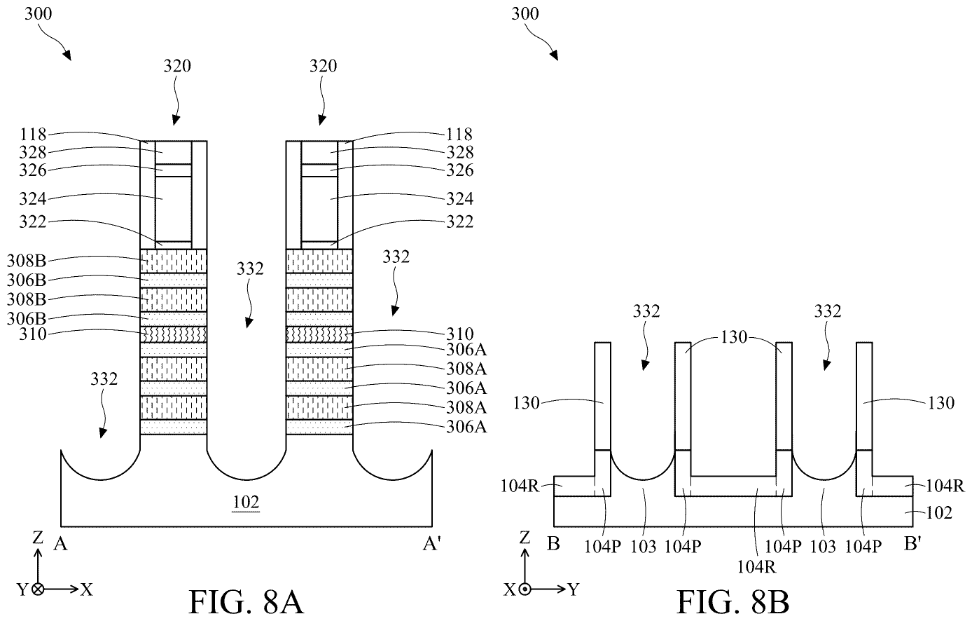

Referring to FIGS. 8A and 8B, the fin structures 316 are recessed to form source/drain trenches 332 in fin structures 316, in accordance with some embodiments. In some embodiments, in each of the fin structures 316, the source/drain trenches 332 are formed on opposite sides of the dummy gate structure 320 in the X-direction. In some embodiments, the source/drain trenches 332 are formed between the side spacers 130 in the Y-direction. More specifically, the source/drain trenches 332 may be formed by performing one or more etching processes to remove portions of the semiconductor layers 306, 308, and 310 and the substrate 102 that do not vertically overlap or be covered by the dummy gate structure 320 and the gate spacers 118.

In some embodiments, a single etchant may be used to remove the substrate 102 and the semiconductor layers 306, 308, and 310. In other embodiments, multiple etchants may be used to perform the etching process. In some embodiments, the side spacers 130 formed on opposite sidewalls of the fin structures 316 in the Y-direction are partially etched during the etching process, so that the heights of the side spacers 130 are reduced, as shown in FIG. 8B. In some embodiments, the parameters of the etching process are configured, such that the top surfaces of the side spacers 130 with the reduced heights are level with or higher than the top surfaces of the source/drain features 122A that will be subsequently formed.

In some embodiments, the isolation structures 104 are also etched during the etching process for forming the source/drain trenches 332. More specifically, portions of the isolation structures 104 that do not vertically overlap or be covered by the dummy gate structure 320 and the side spacers 130 are partially etched. After the etching process, the etched portions of the isolation structures 104 form the recessed portions 104R of the isolation structures 104, and the portions of the isolation structures 104 that are under and covered by the side spacers 130 become protruding portions 104P of the isolation structures 104. In some embodiments, the protruding portions 104P are directly under the side spacers 130 and on opposite sides of the source/drain trenches 332 in the Y-direction, and the recessed portions 104R are between the protruding portions 104P in the Y-direction, as shown in FIG. 8B.

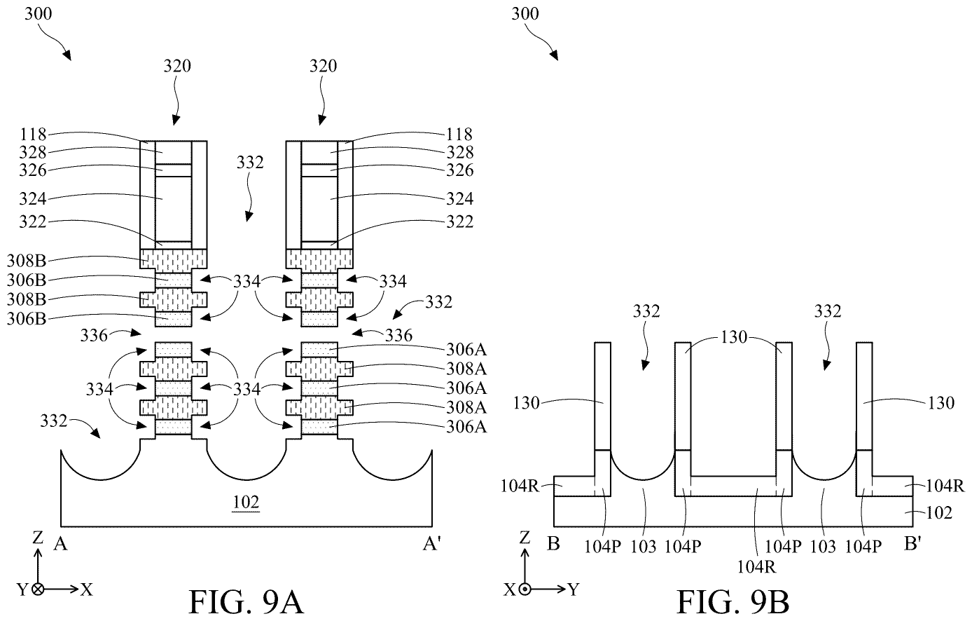

Referring to FIGS. 9A and 9B, the semiconductor layers 306 are partially removed to form inner spacer recesses 334, and the semiconductor layers 310 are removed to form middle recesses 336, in accordance with some embodiments. In some embodiments, the semiconductor layers 306 exposed in the source/drain trenches 332 are partially removed and the semiconductor layers 310 exposed in the source/drain trenches 332 are removed through a selective etching process, and the semiconductor layers 308 are not etched. More specifically, the selective etching process is performed that selectively partially etches the semiconductor layers 306 and selectively etches the semiconductor layers 310 through the source/drain trenches 332, with minimal etching (or substantially no etching) of the semiconductor layers 308 and the substrate 102.

After the selective etching process, middle recesses 336 are formed in the positions previously hold by the semiconductor layers 310, that is, the middle recesses 336 are formed between the topmost semiconductor layers 306A and the bottommost semiconductor layers 306B. After the selective etching process, inner spacer recesses 334 are vertically formed between the semiconductor layers 308, between the middle recesses 336 and the semiconductor layers 308, between the semiconductor layers 308 and the substrate 102, and below the dummy gate structures 320 and the gate spacers 118. The selective etching process may be a dry etching process, a wet etching process, other suitable etching process, or a combination thereof. In some embodiments, the semiconductor layers 308 are also etched during the selective etching process, and the inner spacer recesses 334 partially extend in the Z-direction into the semiconductor layers 308, as shown in FIG. 9A.

In some embodiments, the semiconductor layers 306 are selectively partially etched and the semiconductor layers 310 are selectively etched during the same selective etching process. In these embodiments, the Ge concentrations of the semiconductor layers 306 and 310 and the parameters of the selective etching process are configured so that the inner spacer recesses 334 and the middle recesses 336 are formed during the same selective etching process. In other embodiments, the semiconductor layers 306 are selectively partially etched and the semiconductor layers 310 are selectively etched during different selective etching processes. For example, a first selective etching process is performed to selectively etch the semiconductor layers 310 to form the middle recesses 336, with minimal etching (or substantially no etching) of the semiconductor layers 306 and 308 and the substrate 102. Then, a second selective etching process is performed to partially selectively etch the semiconductor layers 306 to form the inner spacer recesses 334, with minimal etching (or substantially no etching) of the semiconductor layers 308 and substrate 102. In these embodiments, the Ge concentrations of the semiconductor layers 306 and 310 and the parameters of the selective etching process are configured, so as to achieve desired etching selectivity between the semiconductor layers 306 and 310.

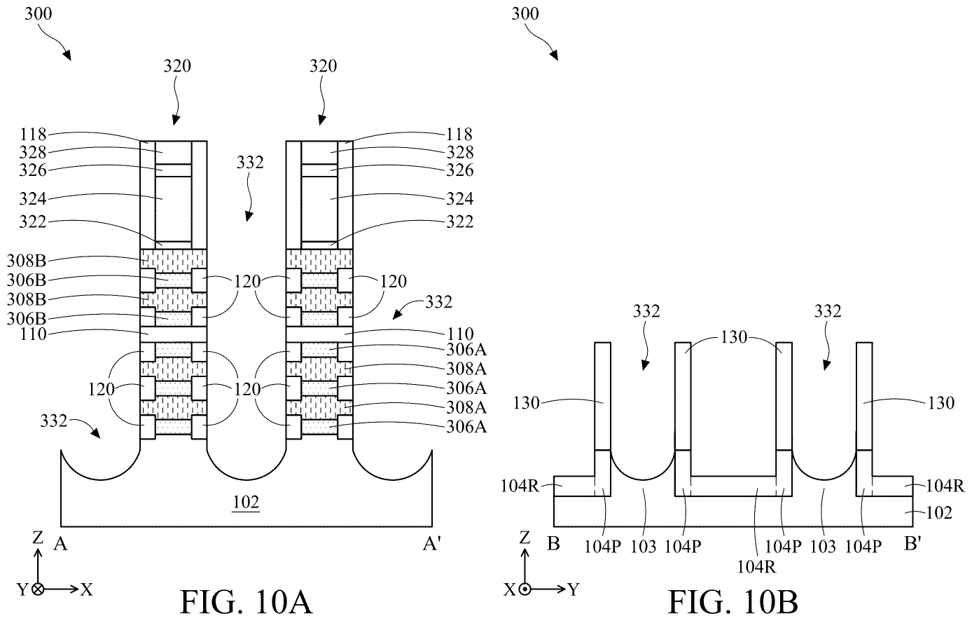

Referring to FIGS. 10A and 10B, the inner spacers 120 are formed in the inner spacer recesses 334 and the middle insulators 110 are formed in the middle recesses 336, in accordance with some embodiments. In some embodiments, a deposition process is performed to form a dielectric material layer into the source/drain trenches 332, the inner spacer recesses 334, and the middle recesses 336. For example, the deposition process may be CVD, PVD, ALD, HDPCVD, MOCVD, RPCVD, PECVD, LPCVD, ALCVD, APCVD, other suitable methods, or combinations thereof. The dielectric material layer partially (or completely) fills the source/drain trenches 332, and fully fills the inner spacer recesses 334 and the middle recesses 336. The deposition process is configured to ensure that the dielectric material layer fills the inner spacer recesses 334 and the middle recesses 336. Furthermore, the dielectric material layer is also conformally formed on the gate spacers 118 and the isolation structures 104.

The dielectric material layer may include a material that is different than the materials of the semiconductor layers 308 and the gate spacers 118 to achieve desired etching selectivity during the etching process. In some embodiments, the dielectric material layer include a dielectric material that includes silicon, oxygen, carbon, nitrogen, other suitable material, or combinations thereof (e.g., SiO₂, SiON, SiOC, SiCN, SiOCN). In some embodiments, the dielectric material layer include a low-k dielectric material, such as those described herein.

Then, in some embodiments, an etching process is performed to selectively etch the dielectric material layer, so as to form the inner spacers 120 in the inner spacer recesses 334 and form the middle insulators 110 in the middle recesses 336 with minimal etching (or substantially no etching) of the semiconductor layers 308, the substrate 102, the dummy gate structures 320, and the gate spacers 118. The etching process may be an anisotropic etching process, such that portions of the dielectric material layer that do not vertically overlap or be covered by the dummy gate structures 320 and the gate spacers 118 are removed. The dielectric material layer on the gate spacers 118 and the isolation structures 104 are also removed.

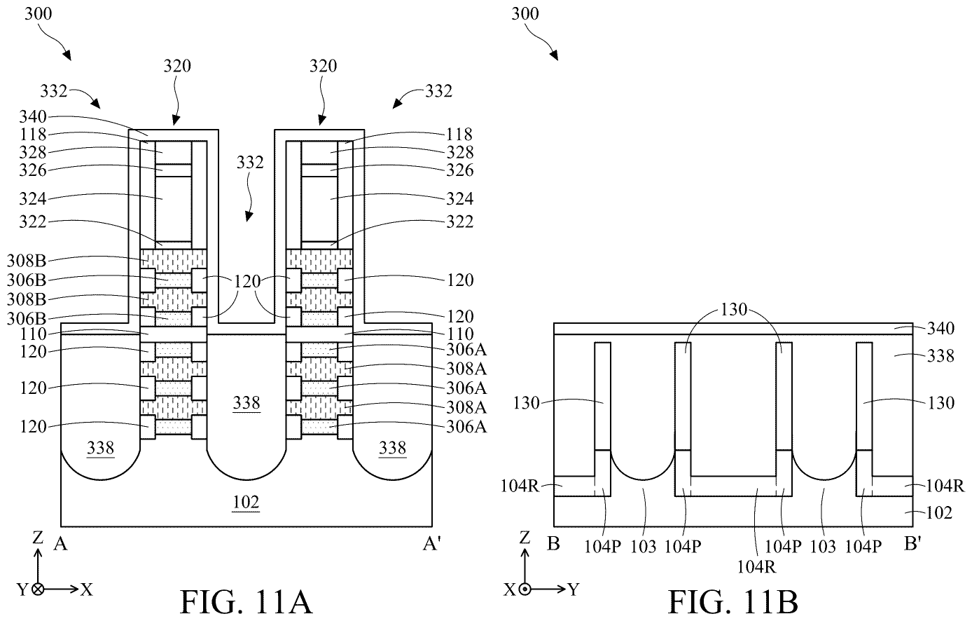

Referring to FIGS. 11A and 11B, dummy material layers 338 and spacer material layers 340 are formed in the source/drain trenches 332, in accordance with some embodiments. More specifically, the dummy material layers 338 are first formed in lower parts of the source/drain trenches 332 to cover the top surfaces of the substrate 102 and the sidewalls of the semiconductor layers 308A (which are used for the lower devices 101A of the CFETs 101) and the inner spacers 120 (which are lower than the middle insulators 110) exposed in the source/drain trenches 332. In some embodiments, the top surfaces of the dummy material layers 338 are lower than the top surfaces of the middle insulators 110. In other embodiments, the top surfaces of the dummy material layers 338 are lower than the bottom surfaces of the middle insulators 110. In some embodiments, the dummy material layers 338 is also formed on the side spacers 130 and the isolation structures 104, as shown in FIG. 11B.

After forming the dummy material layers 338, the spacer material layers 340 are conformally formed over the dummy material layers 338 and on the sidewalls of the source/drain trenches 332. More specifically, the spacer material layers 340 are formed on the top surfaces of the dummy material layers 338, and on the sidewalls of the semiconductor layers 308B (which are used for the upper devices 101B of the CFET 101), the gate spacers 118, and the inner spacers 120 (which are higher than the middle insulators 110).

The dummy material layers 338 may be formed of fluorine-containing polymer and its molecular structure includes silicon (Si), carbon (C), nitrogen (N), or fluorine (F). In some embodiments, the dummy material layers 338 include fluorinated silicone or fluorinated polysilane. In some embodiments, the dummy material layers 338 are spin-on-carbon layers. The dummy material layers 338 may be deposited using CVD, ALD, PECVD, FCVD, or spin-on coating. The spacer material layers 340 may include aluminum oxide (Al₂O₃), and may be deposited using CVD, ALD, PECVD, FCVD, or combinations thereof.

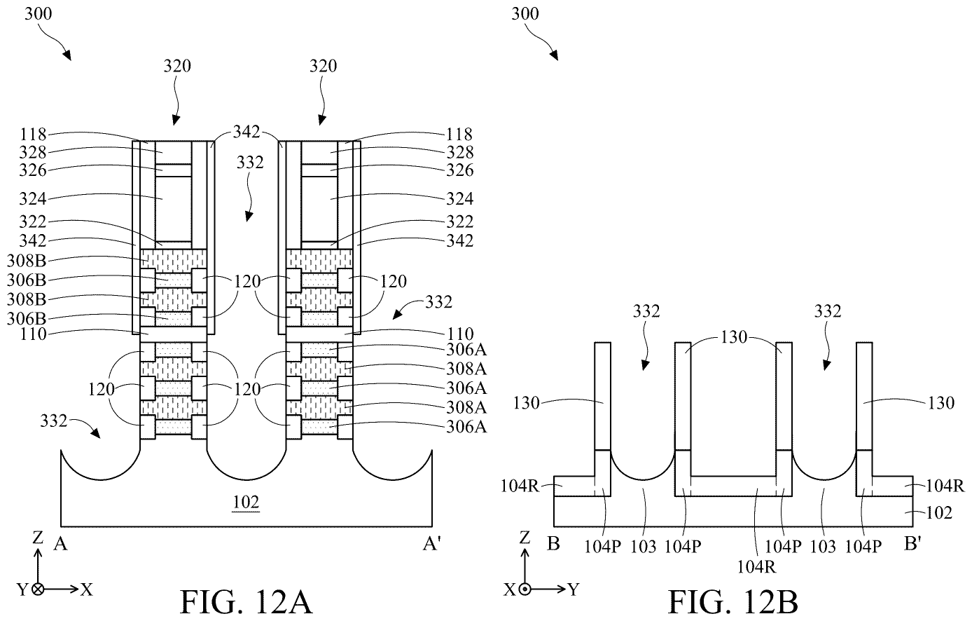

Referring to FIGS. 12A and 12B, the dummy material layers 338 and horizontal portions of the spacer material layers 340 are removed to form cover spacers 342, in accordance with some embodiments. More specifically, an anisotropic etching process is performed to remove the horizontal portions of the spacer material layers 340 to exposed top surfaces of the dummy material layers 338, and then a selective etching process is performed to remove the dummy material layers 338. In some embodiments, vertical portions of the spacer material layers 340 are partially removed or trimmed, and the remained vertical portions form the cover spacers 342. In some embodiments, the cover spacers 342 cover the sidewalls of the gate spacers 118, the semiconductor layers 308B, and the inner spacers 120 over the middle insulators 110, as shown in FIG. 12A. In some embodiments, the cover spacers 342 further partially cover the sidewalls of the middle insulators 110. The selective etching process is performed that selectively etches the dummy material layers 338 below the spacer material layers 340 through the source/drain trenches 332, with minimal etching (or substantially no etching) of the semiconductor layers 308A, the substrate 102, and the inner spacers 120. The selective etching process may be a dry etching process, a wet etching process, other suitable etching process, or combinations thereof.

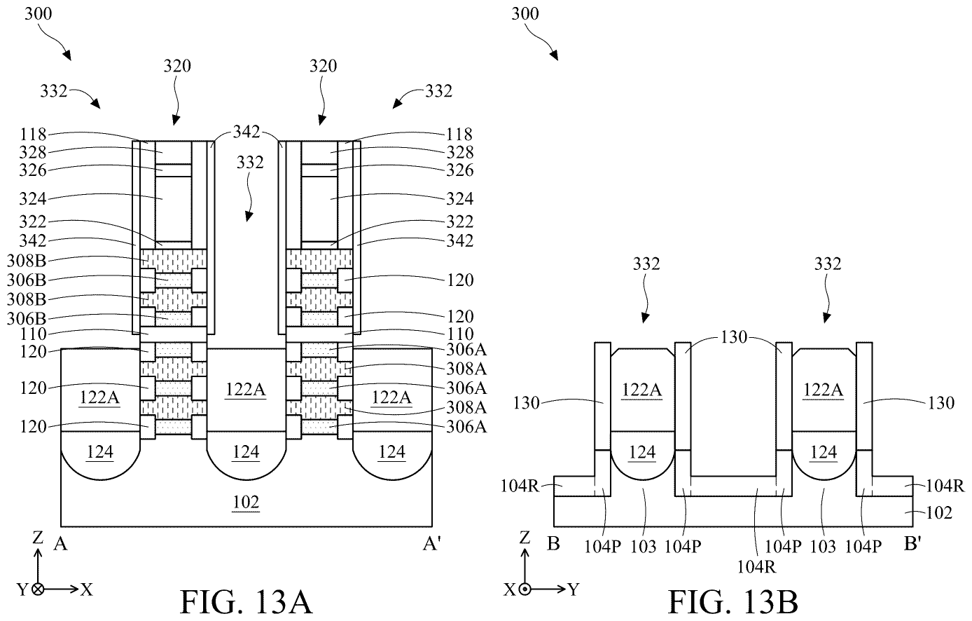

Referring to FIGS. 13A and 13B, the undoped epitaxial layers 124 and the source/drain features 122A are formed in the lower parts of the source/drain trenches 332 and below the cover spacers 342, in accordance with some embodiments. In some embodiments, the undoped epitaxial layers 124 are formed on the substrate 102 exposed in the source/drain trenches 332, and the source/drain features 122A are formed on the undoped epitaxial layers 124. In these embodiments, the undoped epitaxial layers 124 are vertically between and in contact with the source/drain features 122A and the substrate 102 in the Z-direction, and on opposite sides of the dummy gate structures 320 in the X-direction.

In some embodiments, the top surfaces of the undoped epitaxial layers 124 are higher than the topmost surfaces of the substrate 102 (e.g., the top surfaces of the base portions 103). In some embodiments, the undoped epitaxial layers 124 are substantially free of dopants. The undoped epitaxial layers 124 may include Si, Ge, SiGe, other suitable semiconductor materials, or a combination thereof. In some embodiments, the undoped epitaxial layers 124 include silicon that is substantially free of n-type and p-type dopants. In some embodiments, the undoped epitaxial layers 124 are epitaxially grown using an epitaxial growth process such as VPE, MOCVD, MBE, although other deposition processes, such as CVD, LPCVD, PECVD, ALD, UHVCVD, RPCVD, combinations thereof, or the like, may also be utilized. In some embodiments, the undoped epitaxial layers 124 are omitted, so that the source/drain features 122A are in direct contact with the substrate 102.

In some embodiments, the source/drain features 122A are formed in the source/drain trenches 332, on the undoped epitaxial layers 124, and on opposite sides of the dummy gate structure 320 in the X-direction, as shown in FIG. 13A. In some embodiments, the source/drain features 122A are connected to and in contact with the semiconductor layers 308A. In other words, the source/drain features 122A are attached to opposite sides of the semiconductor layers 308A, and thus connect one source/drain feature 122A to another source/drain feature 122A. In some embodiments, the source/drain features 122A may have the top surfaces that extend higher than top surfaces of the topmost semiconductor layers 308A (e.g., in the Z-direction). In some embodiments, the top surfaces of the source/drain features 122A are lower than the bottom surfaces of the cover spacers 342 and the middle insulators 110. In other embodiments, the top surfaces of the source/drain features 122A are higher than the bottom surfaces of the middle insulators 110.

In some embodiments, the source/drain features 122A may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. In some embodiments, the source/drain features 122A are grown from the undoped epitaxial layers 124 and the end portions of the semiconductor layers 308A. The source/drain features 122A are grown from the semiconductor layers 308A rather than the semiconductor layers 308B, it is because that the cover spacers 342 cover the sidewalls of the semiconductor layers 308B.

In some embodiments, the source/drain features 122A are also formed between the side spacers 130 in the Y-direction, as shown in FIG. 13B. In some embodiments, the process parameters of the formation of side spacers 130 and the formation of source/drain features 122A are configured to control the heights of the side spacers 130 and the source/drain features 122A. For example, the top surfaces of the side spacers 130 may be higher than the top surfaces of the source/drain features 122A, as shown in FIG. 13B. Alternatively, the top surfaces of the side spacers 130 may be level with the top surfaces of the source/drain features 122A.

In some embodiments, the workpiece 300 further includes isolation layers (not shown) formed between the source/drain features 122A and the undoped epitaxial layers 124. More specifically, the isolation layers are formed on the undoped epitaxial layers 124, and the source/drain features 122A are formed on the isolation layers. In some embodiments, the isolation layers may be a single layer structure or a multi-layer structure. In some embodiments, the dielectric material of the isolation layers may include Si₃N₄, SiO₂, SiC, SiOC, SION, SiCN, SiOCN, high-k dielectrics, other suitable materials, or combinations thereof. In some embodiments, the isolation layers may be deposited by CVD, PVD, ALD, HDPCVD, MOCVD, RPCVD, PECVD, LPCVD, ALCVD, APCVD, other suitable methods, or combinations thereof.

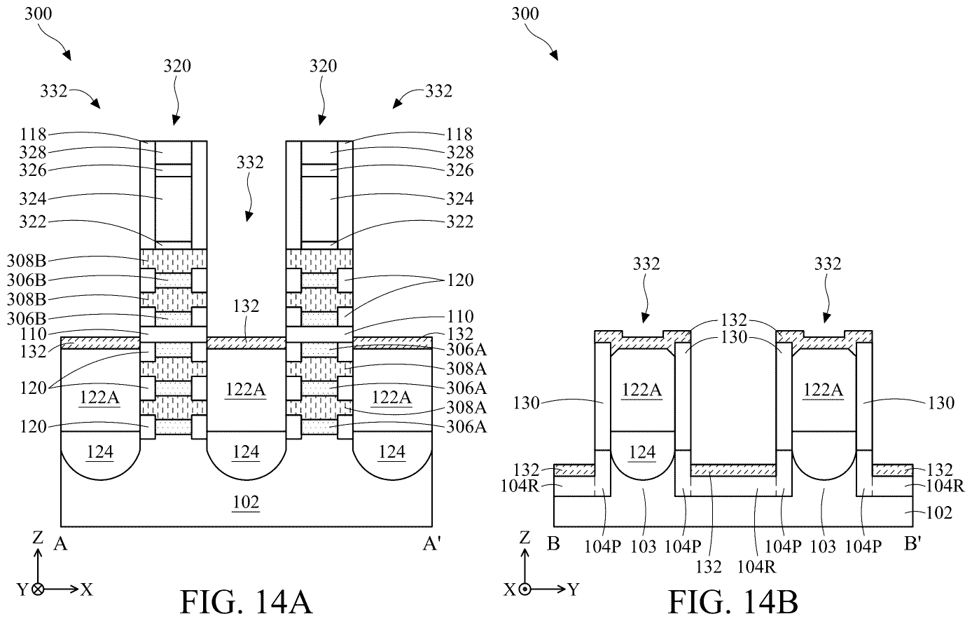

Referring to FIGS. 14A and 14B, the cover spacers 342 are removed from the source/drain trenches 332 through a selective etching process, in accordance with some embodiments. In some embodiments, a selective etching process is performed that selectively etches the cover spacers 342 over the source/drain features 122A through the source/drain trenches 332, with minimal etching (or substantially no etching) of the source/drain features 122A, the semiconductor layers 308B, the gate spacers 118, and the inner spacers 120. The selective etching process may be a dry etching process, a wet etching process, other suitable etching process, or combinations thereof.

Still referring to FIGS. 14A and 14B, after removing the cover spacers 342, the bottom isolation layers 132 are formed on the source/drain features 122A and the side spacers 130, in accordance with some embodiments. More specifically, the bottom isolation layers 132 are formed on the top surfaces of the source/drain features 122A and the top surfaces of the side spacers 130. In further embodiments, the bottom isolation layers 132 are also formed on the top surfaces of the recessed portions 104R of the isolation structures 104. That is, the bottom isolation layers 132 may include first portions and second portions, wherein the first portions are formed on the top surfaces of the source/drain features 122A and the side spacers 130, and the second portions are formed on the recessed portions 104R and between the protruding portions 104P of the isolation structures 104, as shown in FIG. 14B. In the embodiments where the top surfaces of the source/drain features 122A are lower than that of the side spacers 130, the bottom isolation layers 132 may have recesses directly over the source/drain features 122A, as shown in FIG. 14B.

In some embodiments, the bottom isolation layers 132 may include one or more dielectric materials and have a single layer structure or a multi-layer structure. In some embodiments, the dielectric material of the bottom isolation layers 132 may include Si₃N₄, SiO₂, SiC, SiOC, SION, SiCN, SiOCN, high-k dielectrics, other suitable materials, or combinations thereof. In some embodiments, the bottom isolation layers 132 may be deposited by CVD, PVD, ALD, HDPCVD, MOCVD, RPCVD, PECVD, LPCVD, ALCVD, APCVD, other suitable methods, or combinations thereof. In some embodiments, the process parameters of the formation of the bottom isolation layers 132 are configured, so as to deposit the bottom isolation layers 132 in a bottom-up manner.

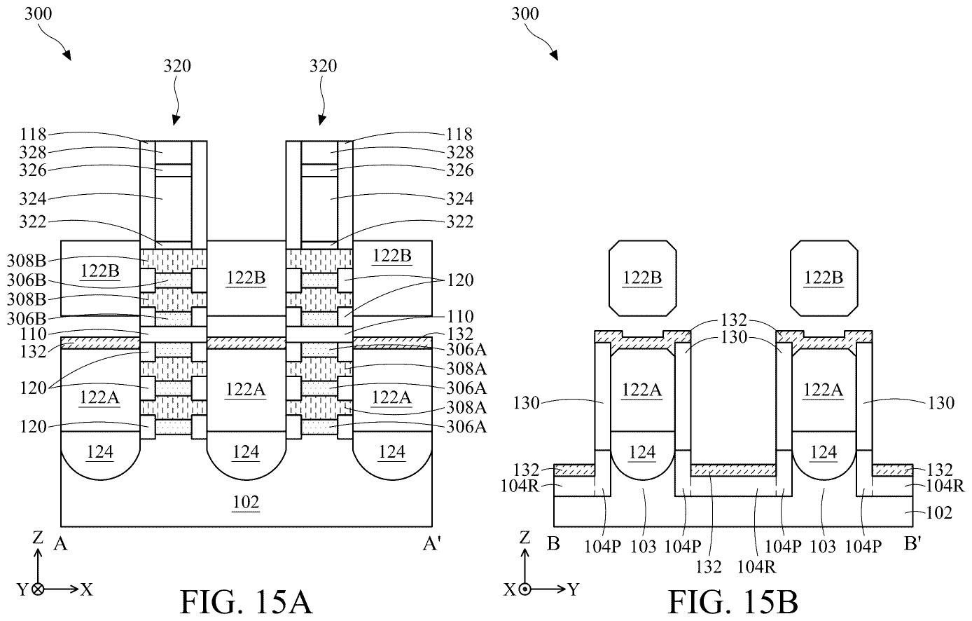

Referring to FIGS. 15A and 15B, the source/drain features 122B are formed in the source/drain trenches 332, over the source/drain features 122A and the bottom isolation layers 132, and on opposite sides of the dummy gate structure 320 in the X-direction, in accordance with some embodiments. More specifically, the source/drain features 122B vertically overlap the source/drain features 122A in the Z-direction. In some embodiments, the source/drain features 122B are spaced apart from the bottom isolation layers 132 in the Z-direction, and thus spaced apart from the source/drain features 122A in the Z-direction.

In some embodiments, the source/drain features 122B are connected to and in contact with the semiconductor layers 308B. In other words, the source/drain features 122B are attached to opposite sides of the semiconductor layers 308B, and thus connect one source/drain feature 122B to another source/drain feature 122B. In some embodiments, the source/drain features 122B may have the top surfaces that extend higher than top surfaces of the topmost semiconductor layers 308B (e.g., in the Z-direction). In some embodiments, the bottom surfaces of the source/drain features 122B are lower than the bottom surfaces of the bottommost semiconductors 308B and higher than top surfaces of the middle insulators 110. In other embodiments, the bottom surfaces of the source/drain features 122B are lower than the top surfaces of the middle insulators 110, such that the source/drain features 122B are in partial contact with the middle insulators 110.

In some embodiments, the source/drain features 122B may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. In some embodiments, the source/drain features 122B are grown from the end portions of the semiconductor layers 308B. The source/drain features 122B are grown from the semiconductor layers 308B rather than the source/drain features 122A, it is because that bottom isolation layers 132 cover the top surfaces of the source/drain features 122A.

In some embodiments, the lower devices 101A are PFETs and the upper devices 101B are NFETs. In these embodiments, the source/drain features 122A are used for PFETs and thus may be referred to as p-type source/drain features, and the source/drain features 122B are used for NFETs and thus may be referred to as n-type source/drain features. In other embodiments, the lower devices 101A are NFETs and the upper devices 101B are PFETs. In these embodiments, the source/drain features 122A are used for NFETs and thus may be referred to as n-type source/drain features, and the source/drain features 122B are used for PFETs and thus may be referred to as p-type source/drain features.

The p-type source/drain features may include epitaxially-grown material selected from a group consisting of boron-doped SiGe, boron-doped SiGeC, boron-doped Ge, boron-doped Si, boron and carbon doped SiGe, or a combination thereof. In some embodiments, the p-type source/drain features may be doped with p-type dopants and have a doping concentration in a range from about 1×10¹⁹/cm³ to 6×10²⁰/cm³. The n-type source/drain features may include epitaxially-grown material selected from a group consisting of SiP, SiC, SiPC, SiAs, Si, or a combination thereof. In some embodiments, the n-type source/drain features may be doped with n-type dopants and have a doping concentration in a range from about 2×10¹⁹/cm³ to 3×10²¹/cm³. The source/drain features 122A and 122B may be doped in-situ or ex-situ. One or more annealing processes may be performed to activate the dopants in the source/drain features 122A and 122B. The annealing processes may include rapid thermal annealing (RTA) and/or laser annealing processes.

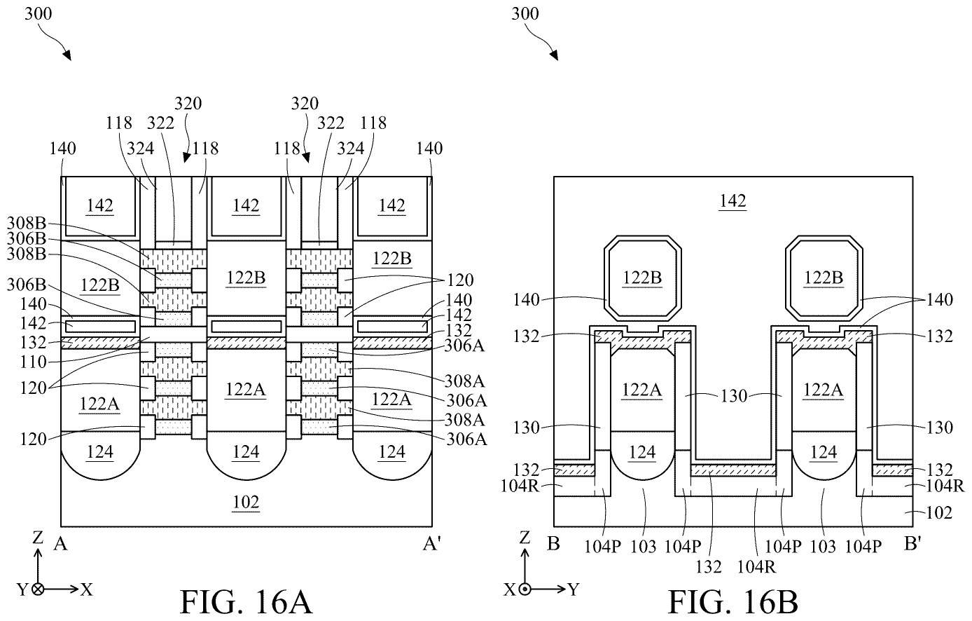

Referring to FIGS. 16A and 16B, the CESLs 140 are formed in the source/drain trenches 332, and the ILD layer 142 is formed on the CESLs 140, in accordance with some embodiments. More specifically, the CESLs 140 are conformally formed on the features exposed by the source/drain trenches 332. In some embodiments, the CESLs 140 are formed on and cover the surfaces of the bottom isolation layers 132 that are on the source/drain features 122A, and formed on the sidewalls of the side spacers 130, as shown in FIG. 16B. The CESLs 140 are also formed on the surfaces of the source/drain features 122B to surround the source/drain features 122B. In some embodiments, the CESLs 140 are further formed on and cover the top surfaces of the bottom isolation layers 132 that are on the recessed portions 104R, and formed on the sidewalls of the exposed portions of the protruding portions 104P, as shown in FIG. 16B.

In some embodiments, the CESLs 140 are further formed on the sidewalls of the gate spacers 118, the middle insulators 110, and some of the inner spacers 120. For example, depending on the positions of the bottom isolation layers 132, the CESLs 140 may be in contact with the middle insulators 110, and in contact with the inner spacers 120 that are in direct contact with and above and/or below the middle insulators 110. In some embodiments, the CESLs 140 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. The CESLs 140 may be formed by CVD, PVD, ALD, HDPCVD, MOCVD, RPCVD, PECVD, LPCVD, ALCVD, APCVD, FCVD, or other suitable methods.

Then, in some embodiments, the ILD layer 142 is formed in the source/drain trenches 332, and is formed on and between the CESLs 140 to fill the space between the CESLs 140 and in the source/drain trenches 332. For example, the ILD layer 142 fills the spaces between the source/drain features 122A (or bottom isolation layers 132) and the source/drain features 122B. More specifically, the ILD layer 142 fills the spaces between the CESLs 140 formed on the bottom isolation layers 132 and the CESLs 140 surrounding the source/drain features 122B. In some embodiments, after forming the ILD layer 142, the source/drain features 122A are separated from the source/drain features 122B by the bottom isolation layers 132, the CESLs 140, and the ILD layer 142, as shown in FIGS. 16A and 16B.

In some embodiments, the ILD layer 142 may include a material that is different than the CESLs 140. In some embodiments, the ILD layer 142 may include tetraethylorthosilicate (TEOS) formed oxide, un-doped silicate glass, or doped silicon oxide such as borophosphosilicate glass (BPSG), FSG, phosphosilicate glass (PSG), boron doped silicon glass (BSG), low-k dielectric materials, other suitable dielectric materials, or combinations thereof. The ILD layer 142 may be formed by CVD, PVD, ALD, HDPCVD, MOCVD, RPCVD, PECVD, LPCVD, ALCVD, APCVD, FCVD, or other suitable methods. After forming the CESLs 140 and the ILD layer 142, a CMP process is performed to reduce heights of the CESLs 140 and the ILD layer 142 and remove the hard masks 326 and 328, until top surface of the dummy gate electrode layers 324 of the dummy gate structures 320 are exposed.

As described above, the bottom isolation layers 132 are formed on the source/drain features 122A of the lower devices 101A, and the source/drain features 122B of the upper devices 101B are formed over and spaced apart from the bottom isolation layers 132. Then, the CESLs 140 and the ILD layers 142 are formed to fill the spaces between the bottom isolation layers 132 and the source/drain features 122B. In this way, the etching back process for etching back the CESLs 140 and the ILD layers 142 before the formation of the source/drain features 122B can be omitted, and another formation process for forming other CESLs and ILD layer on the source/drain features 122B can also be omitted. Therefore, the issues of flatness, process variation, and voids described above can be avoided and the cost can be reduced. Moreover, the side spacers 130 are formed on opposite sides of the source/drain features 122A and have top surfaces that are level with or higher than the top surfaces of the source/drain features 122A. The side spacers 130 can facilitate the formation of the bottom isolation layers 132, so as to increase the uniformity of the bottom isolation layers 132. As a result, the uniformity of the assembly of the bottom isolation layers 132 and the CESLs 140 and the ILD layers 142 (which are formed over the bottom isolation layers 132) may be improved.

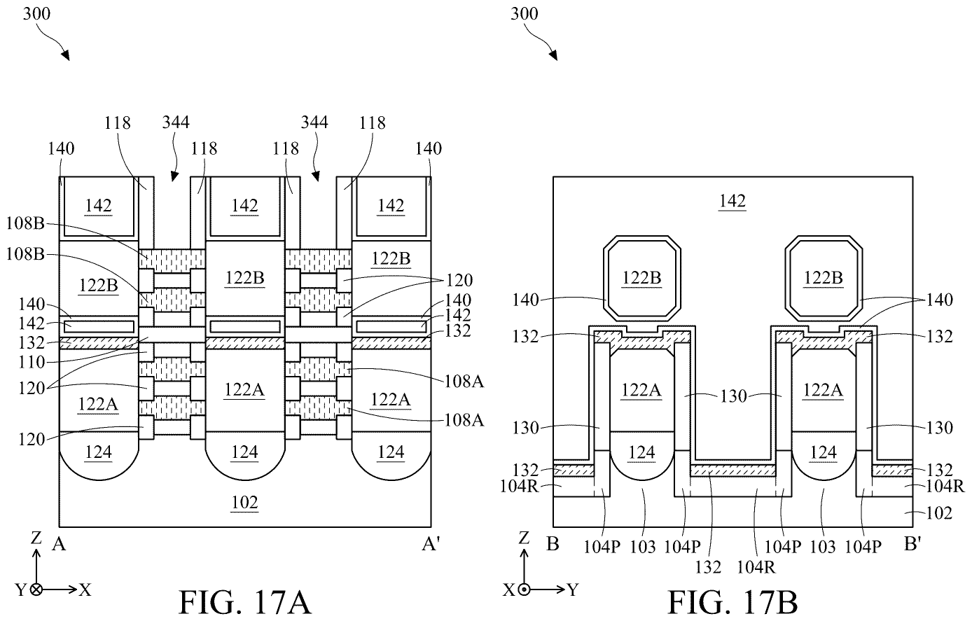

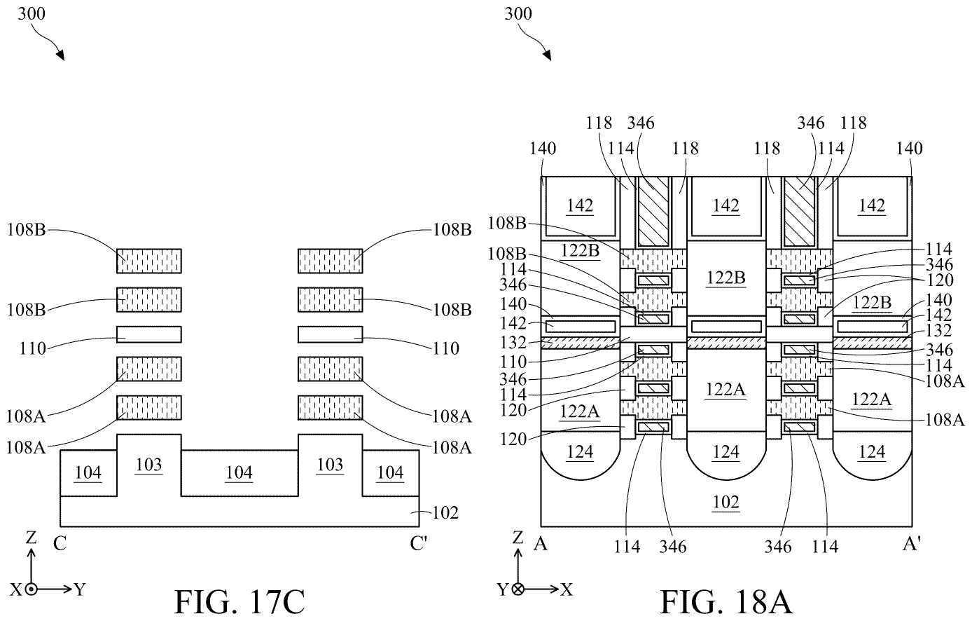

Referring to FIG. 17A-17C, the dummy gate structures 320 are selectively removed through any suitable photolithography and etching processes, in accordance with some embodiments. In some embodiments, the photolithography process may include forming a photoresist layer, exposing the photoresist to a pattern, performing a post-exposure bake process, and developing the photoresist to form a masking element, which exposes a region including the dummy gate structures 320. Then, the dummy gate structures 320 are selectively etched through the masking element. The gate spacers 118 may be used as the masking element or a part thereof. Etch selectivity may be achieved by selecting appropriate etching chemicals, and the dummy gate structures 320 may be removed without substantially affecting the CESLs 140 and the ILD layer 142. The removal of the dummy gate structures 320 creates gate trenches 344. The gate trenches 344 expose the top surfaces of the topmost semiconductor layers 308B that underlie the dummy gate structures 320.

Still referring to FIGS. 17A-17C, the semiconductor layers 306 are selectively removed through the gate trenches 344 to extend the gate trenches 344, using a wet or dry etching process for example, in accordance with some embodiments. After the semiconductor layers 306 are selectively removed, the semiconductor layers 308A and 308B are exposed in the gate trenches 344 to form the nanostructures 108A and 108B. Specifically, the nanostructures 108A (the semiconductor layers 308A) are stacked vertically in the Z-direction, and the nanostructures 108B (the semiconductor layers 308B) are directly over the nanostructures 108A and are stacked vertically in the Z-direction. Such a process may be referred to as a wire/nanowire/nanosheet release process, or a wire/nanowire/nanosheet formation process. The configurations of the nanostructures 108A and 108B have been discussed above, and are not repeated herein.

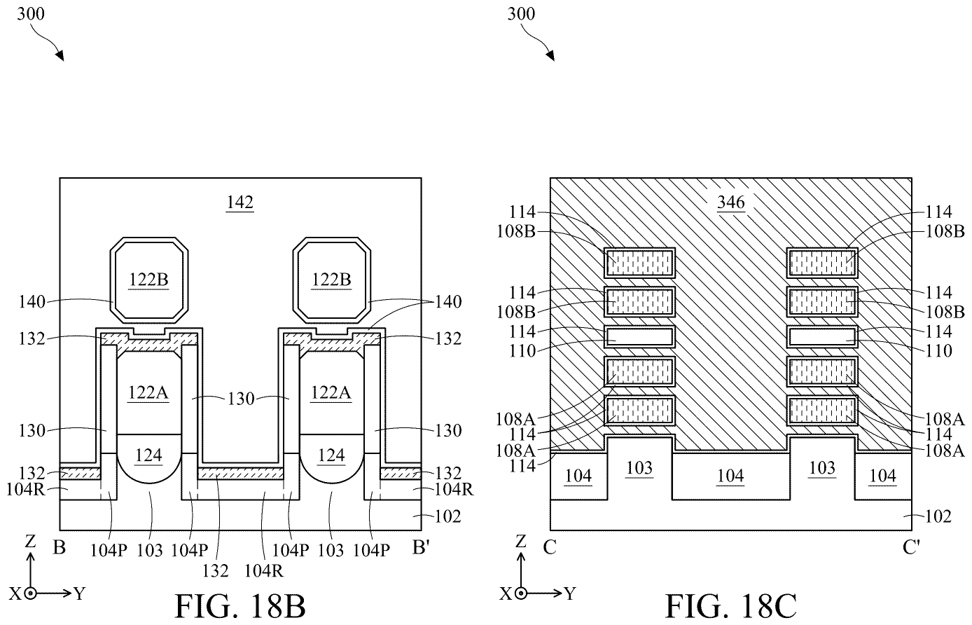

Referring to FIGS. 18A-18C, the gate dielectric layers 114 and gate materials 346 for the gate electrode layers 116A are formed in the gate trenches 344 to wrap around each of the nanostructures 108A and 108B (the semiconductor layers 308A and 308B), in accordance with some embodiments. In some embodiments, the gate dielectric layers 114 are wrapped around each of the nanostructures 108A and 108B, and the gate materials 346 of the gate electrode layers 116A are wrapped around the gate dielectric layers 114 and each of the nanostructures 108A and 108B. Additionally, the gate dielectric layers 114 are also formed on the sidewalls of the inner spacers 120 and the gate spacers 118, as well as over the top surfaces of the substrate 102 and the isolation structures 104.

Referring back to FIGS. 1A-1C, the gate materials 346 in the gate trenches 344 are etched back to expose the nanostructures 108B and form the gate electrode layers 116A, and the gate electrode layers 116B are formed in the gate trenches 344, in accordance with some embodiments. In these embodiments, the resultant device of the workpiece 300 may be fabricated to as the semiconductor device 100 shown in FIGS. 1A-1C. In some embodiments, portions of the gate materials 346 that are wrapped around the nanostructures 108B are removed by one or more etching processes to form the gate electrode layers 116A. The etching processes may be selective etching processes that selectively etch the gate materials 346, with minimal etching (or substantially no etching) of the gate dielectric layers 114, the nanostructures 108B, the gate spacers 118, and the inner spacers 120. The selective etching process may be a dry etching process, a wet etching process, other suitable etching process, or combinations thereof. In some embodiments, after the etching processes, the top surfaces of the gate electrode layers 116A are lower than the bottommost surfaces of the nanostructures 108B. In further embodiments, after the etching processes, the top surfaces of the gate electrode layers 116A are lower than the top surfaces of the middle insulators 110.

Then, in some embodiments, gate materials for the gate electrode layers 116B are formed in the gate trenches 344 to form the gate electrode layers 116B. The gate electrode layers 116B are formed over the gate dielectric layers 114 and the gate electrode layers 116A, and are wrapped around the gate dielectric layers 114 and the nanostructures 108B. As described above, the gate electrode layers 116A may be wrapped around the portions of the gate dielectric layers 114 that are wrapped around the nanostructures 108A, so as to form the first gate structure used for the lower devices 101A of the CFETs 101. The gate electrode layers 116B may be wrapped around the portions of the gate dielectric layers 114 that are wrapped around the nanostructures 108B, so as to form a second gate structure used for the upper devices 101B of the CFETs 101. The first gate structures and the second gate structures constitute the gate structures 112, and the gate structures 112 replace the dummy gate structures 320.

In further embodiments, the gate electrode layers 116A are also formed on portions of the gate dielectric layers 114 that on the lower portions of the middle insulators 110, and the gate electrode layers 116B are also formed on portions of the gate dielectric layers 114 that on the upper portions of the middle insulators 110. In some embodiments, the gate structures 112 further includes the interfacial layers (not shown) formed between the gate dielectric layer 114 and the nanostructures 108. For example, the interfacial layers may include a dielectric material such as SiO₂, HfSiO, or SiON, and may be formed by chemical oxidation, thermal oxidation, CVD, PVD, ALD, HDPCVD, MOCVD, RPCVD, PECVD, LPCVD, ALCVD, APCVD, FCVD, and/or other suitable method.

In some embodiments, the gate dielectric layers 114 may include a dielectric material, such as SiOCN, SiOC, SiCN, SiO₂, SiN, SiC, or other suitable materials. In some embodiments, the gate dielectric layers 114 may include a high-k dielectric material that has a dielectric constant greater than a dielectric constant of SiO₂, which is approximately 3.9. For example, the gate dielectric layers 114 may include HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, SiON, other suitable materials, or combinations thereof. The gate dielectric layers 114 may be formed by chemical oxidation, thermal oxidation, CVD, PVD, ALD, HDPCVD, MOCVD, RPCVD, PECVD, LPCVD, ALCVD, APCVD, FCVD, other suitable methods, or combinations thereof.

The gate electrode layers 116A and 116B each may include a single layer or a multi-layer structure. In some embodiments, the gate electrode layers 116A and 116B each may include a capping layer, a barrier layer, work function metal layers, and a fill material. The gate electrode layers 116A and 116B may be formed using a deposition process such as CVD, PVD, ALD, HDPCVD, MOCVD, RPCVD, PECVD, LPCVD, ALCVD, APCVD, FCVD, or the like, although any suitable deposition process may be used. The capping layer may be formed of a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The barrier layer may be formed of a material different from the capping layer. In some embodiments, the barrier layer may be formed of a material such as one or more layers of a metallic material. For example, the metallic material may be TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

In the embodiments where the lower devices 101A are PFETs and the upper devices 101B are NFETs, the gate electrode layers 116A may include p-type work function metal layers, and the gate electrode layers 116B may include n-type work function metal layers. In the embodiments where the lower devices 101A are NFETs and the upper devices 101B are PFETs, the gate electrode layers 116A may include n-type work function metal layers, and the gate electrode layers 116B may include p-type work function metal layers. The n-type and p-type work function metal layers may include conductive materials tuned to have a desired work function (e.g., an n-type work function or a p-type work function). In some embodiments, the n-type and p-type work function metal layers may include a material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the fill material may include a suitable conductive material, such as Al, W, and/or Cu.

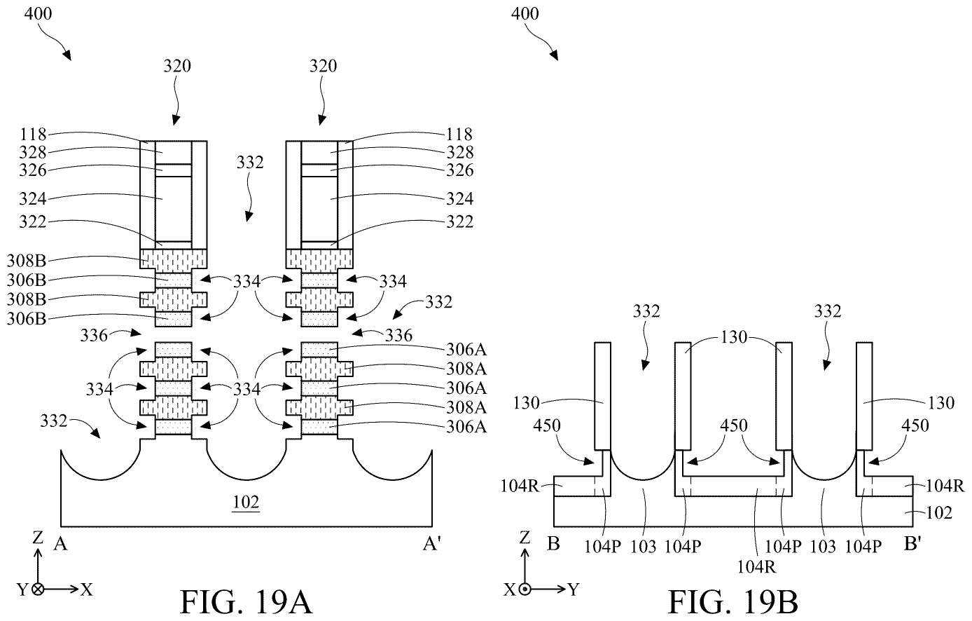

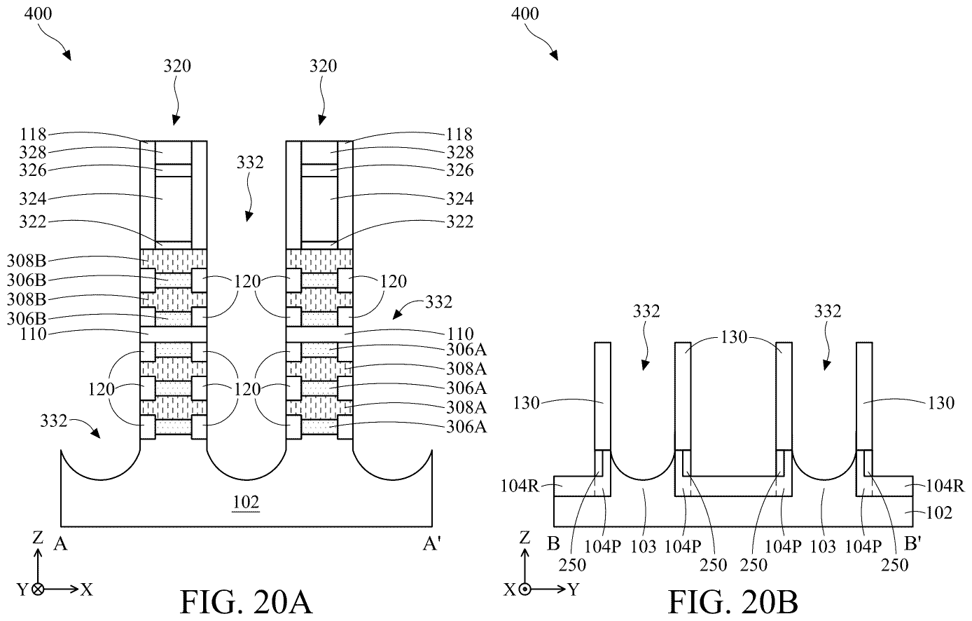

FIGS. 19A to 20B illustrate the workpiece 400 at various fabrication stages, in accordance with some alternative embodiments of the present disclosure. FIGS. 19A and 20A are X-Z cross-sectional views of the workpiece 400 at various fabrication stages along line A-A′ of FIG. 5, and FIGS. 19B and 20B are Y-Z cross-sectional views of the workpiece 400 at various fabrication stages along line B-B′ of FIG. 5, in accordance with some embodiments. The fabrication stage shown in FIGS. 19A and 19B follows the fabrication stage shown in FIGS. 8A and 8B.

Referring to FIGS. 19A and 19B, the semiconductor layers 306 are partially removed to form inner spacer recesses 334, and the semiconductor layers 310 are removed to form middle recesses 336, in accordance with some embodiments. As described above with reference to FIGS. 9A and 9B, an selective etching process is performed that selectively partially etches the semiconductor layers 306 and selectively etches the semiconductor layers 310 through the source/drain trenches 332, with minimal etching (or substantially no etching) of the semiconductor layers 308 and the substrate 102. After the selective etching process, the middle recesses 336 and the inner spacer recesses 334 are formed.

In further embodiments, the selective etching process also selectively partially etches the isolation structures 104. In some embodiments, the protruding portions 104P of the isolation structures 104 are etched to form side recesses 450 through the selective etching process. In some embodiments, the side recesses 450 are directly under the side spacers 130, as shown in FIG. 19B. In some embodiments, the recessed portions 104R of the isolation structures 104 are also etched by the selective etching process, such that the heights of the recessed portions 104R are reduced after the selective etching process.

Referring to FIGS. 20A and 20B, the inner spacers 120 are formed in the inner spacer recesses 334 and the middle insulators 110 are formed in the middle recesses 336, in accordance with some embodiments. As described above with reference to FIGS. 10A and 10B, a deposition process is performed to form a dielectric material layer into the source/drain trenches 332, the inner spacer recesses 334, and the middle recesses 336. Then, an etching process is performed to selectively etch the dielectric material layer, so as to form the inner spacers 120 in the inner spacer recesses 334 and form the middle insulators 110 in the middle recesses 336 with minimal etching (or substantially no etching) of the semiconductor layers 308, the substrate 102, the dummy gate structures 320, and the gate spacers 118.

In further embodiments, the deposition process also forms the dielectric material layer into the side recesses 450, and then the etching process selectively etches the dielectric material layer, so as to form the side dielectric layers 250 in the side recesses 450, as shown in FIG. 20B. In some embodiments, the deposition process also forms the dielectric material layer on the top surfaces of the recessed portions 104R, while the portions of the dielectric material layer formed on the recessed portions 104R are removed through the etching process. The deposition process, the etching process, and the material of the dielectric material layer have been discussed above with reference to FIGS. 10A and 10B, and are not repeated herein.

Referring back to FIGS. 2A and 2B, the undoped epitaxial layers 124, the source/drain features 122A and 122B, the bottom isolation layers 132, the CESLs 140, the ILD layer 142, and the gate structures 112 are formed, in accordance with some embodiments. In these embodiments, the resultant device of the workpiece 400 may be fabricated to as the semiconductor device 200 shown in FIGS. 2A and 2B.

The materials and methods used in forming the undoped epitaxial layers 124 and the source/drain features 122A have been discussed above with reference to FIGS. 11A-13B, and are not repeated herein. The material and method used in forming the bottom isolation layers 132 have been discussed above with reference to FIGS. 14A and 14B, and are not repeated herein. The material and method used in forming the source/drain features 122B have been discussed above with reference to FIGS. 15A and 15B, and are not repeated herein. The materials and methods used in forming the CESLs 140 and the ILD layer 142 have been discussed above with reference to FIGS. 16A and 16B, and are not repeated herein. The material and method used in forming the gate structures 112 have been discussed above with reference to FIGS. 17A-18C and 1A-1C, and are not repeated herein.

The embodiments disclosed herein relate to semiconductor structures and their forming methods, and more particularly to structures and methods that include forming bottom isolation layers on the lower S/D features, and forming upper S/D features that is spaced apart from the bottom isolation layers. Then, the CESLs and ILD layer are formed to fill the spaces between the bottom isolation layers and the upper S/D features, as well as formed over the upper S/D features. In this way, the etching back process for etching the CESLs and ILD layer before forming the upper S/D features can be omitted. Therefore, the issues of flatness, process variation, and voids between the CESLs/ILD layer and the upper S/D features can be avoided and the cost can be reduced. Moreover, the embodiments discussed herein further include forming side spacers on opposite sides of the lower S/D features and that have top surfaces that are level with or higher than top surfaces of the lower S/D features. The side spacers can facilitate the formation of bottom isolation layers, so as to increase the uniformity of the bottom isolation layers. As a result, the uniformity of the assembly of the bottom isolation layers and the separating structures may be improved.

In one exemplary aspect, the present disclosure is directed to a method of forming a semiconductor structure. The method includes forming a fin structure over a substrate, forming a dummy gate structure over the fin structure, and etching the fin structure to form source/drain trenches on opposite sides of the dummy gate structure. The fin structure includes a first stack, a second stack over the first stack, and a first semiconductor layer between the first stack and the second stack. The method further includes forming first source/drain features in the source/drain trenches, depositing bottom isolation layers on top surfaces of the first source/drain features, and forming second source/drain features in the source/drain trenches and over the bottom isolation layers. The second source/drain features are spaced apart from the bottom isolation layers. The method further includes depositing first contact etch stop layers (CESLs) in the source/drain trenches, and depositing an interlayer dielectric (ILD) layer in the source/drain trenches. The first CESLs cover top surfaces of the bottom isolation layers and surround the second source/drain features. The ILD layer fills spaces between the first source/drain features and the second source/drain features.

In another exemplary aspect, the present disclosure is directed to a method of forming a semiconductor structure. The method includes forming a fin structure over a substrate, forming a dummy gate structure over the fin structure, and forming side spacers on opposite sides of the fin structure. The fin structure includes a first stack including first semiconductor layers and second semiconductor layers alternately stacked, a second stack over the first stack and including third semiconductor layers and fourth semiconductor layers alternately stacked, and a fifth semiconductor layer between the first stack and the second stack. The method further includes etching the fin structure to form source/drain trenches on opposite sides of the dummy gate structure, performing an etching process to remove the fifth semiconductor layer and to partially recess the first semiconductor layers and the third semiconductor layers, so as to form a middle recess and inner spacer recesses, respectively, and depositing a dielectric material to form a middle insulator in the middle recess and to form inner spacers in the inner spacer recesses. The source/drain trenches are between the side spacers. The method further includes forming first source/drain features in the source/drain trenches, depositing bottom isolation layers on the first source/drain features and the side spacers; and forming second source/drain features in the source/drain trenches and over the bottom isolation layers. The second source/drain features are spaced apart from the bottom isolation layers.

In yet another exemplary aspect, the present disclosure is directed to a semiconductor structure. The semiconductor structure includes a first transistor and a second transistor stacked with the first transistor. The first transistor includes first nanostructures over a substrate and spaced apart from each other in a vertical direction, first source/drain features attached to opposite sides of the first nanostructures in a first horizontal direction, and side spacers formed on opposite sides of the first source/drain features in the first horizontal direction. The second transistor includes second nanostructures over the first nanostructures and spaced apart from each other in the vertical direction, and second source/drain features attached to opposite sides of the second nanostructures in the first horizontal direction and disposed over the first source/drain features. The semiconductor structure further includes bottom isolation layers formed on top surfaces of the first source/drain features and the side spacers, a middle insulator formed between the first nanostructures and the second nanostructures, and a gate structure wrapped around each of the first nanostructures and the second nanostructures. The bottom isolation layers are spaced apart from the second source/drain features.

In yet another exemplary aspect, the present disclosure is directed to a method of forming a semiconductor structure. The method includes forming a fin structure over a substrate, forming isolation structures on opposite sides of the fin structure, forming a dummy gate structure over the fin structure, forming gate spacers on opposite sides of the dummy gate structure, and forming side spacers on the opposite sides of the fin structure and on the isolation structures. The fin structure includes a first stack, a second stack over the first stack, and a first semiconductor layer between the first stack and the second stack. The method further includes performing a first etching process to form source/drain trenches in the fin structure and on the opposite sides of the dummy gate structure and to partially recess the isolation structures. The source/drain trenches are between the side spacers, and the recessed isolation structures include protruding portions under the side spacers and recessed portions. The method further includes performing a second etching process to partially recess the protruding portions to form side recesses, and depositing a dielectric material to form side dielectric layers in the side recesses. The method further includes forming first source/drain features in the source/drain trenches, depositing bottom isolation layers on top surfaces of the first source/drain features and the side spacers, and forming second source/drain features in the source/drain trenches and over the bottom isolation layers. The second source/drain features are spaced apart from the bottom isolation layers.

In some embodiments, the first stack includes second semiconductor layers and third semiconductor layers alternately stacked, and the second stack includes fourth semiconductor layers and fifth semiconductor layers alternately stacked.

In some embodiments, the second etching process further removes the first semiconductor layer and partially recesses the second semiconductor layers and the fourth semiconductor layers, so as to form a middle recess and inner spacer recesses, respectively. The depositing of the dielectric material further forms a middle insulator in the middle recess and inner spacers in the inner spacer recesses.

In some embodiments, the bottom isolation layers include first portions and second portions. The first portions are formed on the top surfaces of the first source/drain features and the side spacers, and the second portions are formed on top surfaces of the recessed portions of the isolation structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a fin structure over a substrate, wherein the fin structure comprises a first stack, a second stack over the first stack, and a first semiconductor layer between the first stack and the second stack;
forming a dummy gate structure over the fin structure;
etching the fin structure to form source/drain trenches on opposite sides of the dummy gate structure;
forming first source/drain features in the source/drain trenches;
depositing bottom isolation layers on top surfaces of the first source/drain features;
forming second source/drain features in the source/drain trenches and over the bottom isolation layers, wherein the second source/drain features are spaced apart from the bottom isolation layers;
depositing first contact etch stop layers (CESLs) in the source/drain trenches, wherein the first CESLs cover top surfaces of the bottom isolation layers and surround the second source/drain features; and
depositing an interlayer dielectric (ILD) layer in the source/drain trenches, wherein the ILD layer fills spaces between the first source/drain features and the second source/drain features.

2. The method of claim 1,
wherein the first stack comprises second semiconductor layers and third semiconductor layers alternately stacked; and
wherein the second stack comprises fourth semiconductor layers and fifth semiconductor layers alternately stacked.

3. The method of claim 2,
wherein a topmost one of the second semiconductor layers and the a topmost one of the fourth semiconductor layers are in direct contact with the first semiconductor layer; and
wherein a first Ge concentration of the first semiconductor layer is higher than a second Ge concentration of the second semiconductor layers and the fourth semiconductor layers.

4. The method of claim 2, further comprising:
removing the dummy gate structure, the second semiconductor layers, and the fourth semiconductor layers to form a gate trench;
depositing a first gate material in the gate trench;
partially removing the first gate material to form a first gate structure; and
depositing a second gate material on the first gate structure to form a second gate structure.

5. The method of claim 2,
wherein the forming of the first source/drain features comprises epitaxially growing the first source/drain features from end portions of the third semiconductor layers exposed in the source/drain trenches; and
wherein the forming of the second source/drain features comprises epitaxially growing the second source/drain features from end portions of the fifth semiconductor layers exposed in the source/drain trenches.

6. The method of claim 1, further comprising:
before the forming of the first source/drain features, depositing dummy material layers in bottoms of the source/drain trenches;
depositing first spacer layers on top surfaces of the dummy material layers and sidewalls of the source/drain trenches; and
removing the dummy material layers and horizontal portions of the first spacer layers.

7. The method of claim 1, further comprising:
depositing a second spacer layer on the dummy gate structure and the fin structure; and
etching the second spacer layer to form gate spacers on the opposite sides of the dummy gate structure and to form side spacers on opposite sides of the fin structure;
wherein top surfaces of the side spacers are higher than the top surfaces of the first source/drain features.

8. The method of claim 7, further comprising:
forming isolation structures on the opposite sides of the fin structure,
wherein the side spacers are formed on the isolation structures,
wherein the forming of the source/drain trenches further comprises partially recessing the isolation structures, such that portions of the isolation structures covered by the side spacers form protruding portions under the side spacers.

9. A method of forming a semiconductor structure, comprising:
forming a fin structure over a substrate, wherein the fin structure comprises:
a first stack comprising first semiconductor layers and second semiconductor layers alternately stacked;
a second stack over the first stack and comprising third semiconductor layers and fourth semiconductor layers alternately stacked; and
a fifth semiconductor layer between the first stack and the second stack;
forming a dummy gate structure over the fin structure;
forming side spacers on opposite sides of the fin structure;
etching the fin structure to form source/drain trenches on opposite sides of the dummy gate structure, wherein the source/drain trenches are between the side spacers;
performing an etching process to remove the fifth semiconductor layer and to partially recess the first semiconductor layers and the third semiconductor layers, so as to form a middle recess and inner spacer recesses, respectively;
depositing a dielectric material to form a middle insulator in the middle recess and to form inner spacers in the inner spacer recesses;
forming first source/drain features in the source/drain trenches;
depositing bottom isolation layers on the first source/drain features and the side spacers; and
forming second source/drain features in the source/drain trenches and over the bottom isolation layers, wherein the second source/drain features are spaced apart from the bottom isolation layers.

10. The method of claim 9, further comprising:
before the forming of the first source/drain features, depositing dummy material layers in bottoms of the source/drain trenches;
depositing spacer material layers on top surfaces of the dummy material layers and sidewalls of the source/drain trenches; and
removing the dummy material layers and horizontal portions of the spacer material layers to form spacer layers.

11. The method of claim 10, wherein the spacer layers cover the inner spacers that are over the middle insulator and cover the fourth semiconductor layers.

12. The method of claim 9, further comprising:
depositing first contact etch stop layers (CESLs) in the source/drain trenches to cover top surfaces of the bottom isolation layers and surround the second source/drain features; and
depositing an interlayer dielectric (ILD) layer to fill the source/drain trenches, wherein the ILD layer fills spaces between the first source/drain features and the second source/drain features.

13. The method of claim 12, wherein the first source/drain features are spaced apart from the second source/drain features by the bottom isolation layers, the first CESLs, and the ILD layer.

14. The method of claim 9, wherein the bottom isolation layers are partially in contact with the middle insulator and the inner spacers that are below and in direct contact with the middle insulator.

15. The method of claim 9, further comprising:
removing the dummy gate structure, the first semiconductor layers, and the third semiconductor layers to form a gate trench;
depositing a gate dielectric layer to be wrapped around each of the second semiconductor layers, the fourth semiconductor layers, and the fifth semiconductor layer; and
forming a first gate electrode layer and a second gate electrode layer on the first gate electrode layer to form a gate structure.

16. The method of claim 15, wherein a top surface of the first gate electrode layer is lower than a top surface of the middle insulator, and a bottom surface of the second gate electrode layer is higher than a bottom surface of the middle insulator.

17. A semiconductor structure, comprising:
a first transistor, comprising:
first nanostructures over a substrate, wherein the first nanostructures are spaced apart from each other in a vertical direction;
first source/drain features, attached to opposite sides of the first nanostructures in a first horizontal direction; and
side spacers, formed on opposite sides of the first source/drain features in a second horizontal direction;
a second transistor stacked with the first transistor, wherein the second transistor comprises:
second nanostructures over the first nanostructures, wherein the second nanostructures are spaced apart from each other in the vertical direction; and
second source/drain features, attached to opposite sides of the second nanostructures in the first horizontal direction and disposed over the first source/drain features;
bottom isolation layers, formed on top surfaces of the first source/drain features and the side spacers, wherein the bottom isolation layers are spaced apart from the second source/drain features;
a middle insulator, formed between the first nanostructures and the second nanostructures; and
a gate structure, wrapped around each of the first nanostructures and the second nanostructures.

18. The semiconductor structure of claim 17, wherein the top surfaces of the side spacers are higher than the top surfaces of the first source/drain features.

19. The semiconductor structure of claim 17, further comprising:
first contact etch stop layers (CESLs), formed on top surfaces of the bottom isolation layers and surrounding the second source/drain features; and
an interlayer dielectric (ILD) layer, formed on the first CESLs.

20. The semiconductor structure of claim 19, wherein the second source/drain features are spaced apart from the first source/drain features by the bottom isolation layers, the first CESLs, and the ILD layer.
